(19) United States
(12) Patent Application Publication
(10) Pub. No.: US 2026/0150346 A1
(43) Pub. Date: May 28, 2026

(54) SEMICONDUCTOR DEVICE AND MANUFACTURING METHOD OF SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Shiyuu NUMATA, Atsugi (JP); Tsutomu MURAKAWA, Isehara (JP); Motomu KURATA, Isehara (JP)

(21) Appl. No.: 19/393,712

(22) Filed: Nov. 19, 2025

(30) Foreign Application Priority Data
Nov. 28, 2024 (JP) 2024-207489

(51) Int. Cl. H10D 30/67; H10B 12/00; H10D 30/01; H10D 64/62; H10K 59/121

(52) U.S. Cl. CPC H10D 30/6755; H10D 30/031; H10D 30/6713; H10D 30/6757; H10D 64/62; H10B 12/30; H10K 59/1213

(57) ABSTRACT

A semiconductor device using a high-quality semiconductor film is provided. The semiconductor device includes a substrate, a semiconductor layer, a gate insulating layer, and a gate electrode. The semiconductor layer is in contact with a top surface of the substrate and includes a first region overlapping with the gate electrode with the gate insulating layer therebetween, and a second region and a third region between which the first region is interposed. The substrate has a single crystal structure. The semiconductor layer includes indium oxide having a single crystal structure. The second region and the third region include a first element.

### BACKGROUND OF THE INVENTION

### 1. Field of the Invention

One embodiment of the present invention relates to a semiconductor device, a memory device, a display device, and an electronic apparatus.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic apparatus, a lighting device, an input device, an input/output device, a driving method thereof, and a manufacturing method thereof. A semiconductor device generally means a device that can function by utilizing semiconductor characteristics.

### 2. Description of the Related Art

In recent years, semiconductor devices have been developed and mainly used for LSI, a CPU, a memory, and the like. A CPU is an aggregation of semiconductor elements; the CPU includes a semiconductor integrated circuit (including at least a transistor and a memory) formed into a chip by processing a semiconductor wafer, and is provided with an electrode that is a connection terminal.

An IC chip including a semiconductor circuit such as LSI, a CPU, or a memory is mounted on a circuit board, for example, a printed wiring board, and used as one of components of a variety of electronic apparatuses.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a material of a semiconductor thin film that can be used in a transistor. As another material, an oxide semiconductor has been attracting attention.

It is known that a transistor using an oxide semiconductor has an extremely low leakage current in a non-conduction state. For example, Patent Document 1 discloses a low-power CPU utilizing the characteristic of a low leakage current of a transistor using an oxide semiconductor. Patent Document 2 discloses a memory device or the like that uses an oxide semiconductor and can retain stored data for a long time.

Non-Patent Document 1 reports a polycrystalline indium oxide film with high Hall mobility and a transistor using the polycrystalline indium oxide film. Non-Patent Document 2 reports use of In₂O₃ for a thin film transistor.

### REFERENCES

### Patent Documents

[Patent Document 1] Japanese Published Patent Application No. 2012-257187
[Patent Document 2] Japanese Published Patent Application No. 2011-151383

### Non-Patent Documents

[Non-Patent Document 1] Y. Magari et al., “High-mobility hydrogenated polycrystalline In₂O₃ (In₂O₃:H) thin-film transistors”, Nature Communications 13, 1078, (2022).
[Non-Patent Document 2] Dhananjay and C. W. Chu, “Realization of In₂O₃ thin film transistors through reactive evaporation process” Appl. Phys. Lett. 91, 132111 (2007).
[Non-Patent Document 3] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a semiconductor device using a high-quality semiconductor film. Another object is to provide a semiconductor device using a single crystal oxide semiconductor film. Another object is to provide a high-performance semiconductor device. Another object is to provide a semiconductor device with favorable electrical characteristics. Another object is to provide a highly reliable semiconductor device. Another object is to provide a low-power semiconductor device.

An object of one embodiment of the present invention is to provide a semiconductor device having a novel structure. An object of one embodiment of the present invention is to at least alleviate at least one of problems in the conventional art.

Note that the description of these objects does not preclude the existence of other objects. In one embodiment of the present invention, there is no need to achieve all of these objects. Objects other than these can be derived from the description of the specification, the drawings, the claims, and the like.

One embodiment of the present invention is a semiconductor device including a substrate, a semiconductor layer, a gate insulating layer, and a gate electrode. The semiconductor layer is in contact with a top surface of the substrate and includes a first region overlapping with the gate electrode with the gate insulating layer therebetween, and a second region and a third region between which the first region is interposed. The substrate has a single crystal structure. The semiconductor layer includes indium oxide having a single crystal structure. The second region and the third region include a first element. The first element is at least one of titanium, tantalum, tungsten, molybdenum, tin, silicon, germanium, zirconium, hafnium, antimony, magnesium, hydrogen, boron, and phosphorus.

Another embodiment of the present invention is a semiconductor device including a substrate, a semiconductor layer, a gate insulating layer, and a gate electrode. The semiconductor layer is in contact with a top surface of the substrate and includes a first region overlapping with the gate electrode with the gate insulating layer therebetween, and a second region and a third region between which the first region is interposed. The substrate includes aluminum oxide having a single crystal structure, and the surface of the substrate that is in contact with the semiconductor layer is the (0001) plane or a plane equivalent to the (0001) plane. The semiconductor layer includes indium oxide having a single crystal structure, and a surface of the semiconductor layer that is in contact with the substrate is the (111) plane or a plane equivalent to the (111) plane. The second region and the third region include a first element. The first element is at least one of titanium, tantalum, tungsten, molybdenum, tin, silicon, germanium, zirconium, hafnium, antimony, magnesium, hydrogen, boron, and phosphorus.

In the above, the off-angle of the substrate is preferably 0°. Alternatively, in the above, the off-angle of the substrate is preferably greater than 0° and less than or equal to 10°. Furthermore, the direction of the off-angle is preferably parallel to the [−2110] orientation of the substrate or an orientation equivalent to the [−2110] orientation.

Another embodiment of the present invention is a method for manufacturing a semiconductor device; the method includes the steps of forming a single crystal semiconductor film over a single crystal substrate, processing the semiconductor film to form an island-shaped semiconductor layer, forming a mask layer covering a first region of the semiconductor layer, adding a first element to a second region and a third region of the semiconductor layer between which the first region is interposed, forming a first insulating layer covering the semiconductor layer and the mask layer, planarizing the first insulating layer until a top surface of the mask layer is exposed, removing the mask layer to form a groove portion reaching the semiconductor layer in the first insulating layer, and sequentially forming a gate insulating layer and a gate electrode in the groove portion. Here, aluminum oxide having a single crystal structure is used for the single crystal substrate. Indium oxide is used for the semiconductor layer. At least one of titanium, tantalum, tungsten, molybdenum, tin, silicon, germanium, zirconium, hafnium, antimony, magnesium, hydrogen, boron, and phosphorus is used as the first element.

In the above, a single crystal substrate whose formation surface is the (0001) plane or a plane equivalent to the (0001) plane is preferably used as the single crystal substrate. Furthermore, a film whose plane in contact with the single crystal substrate is the (111) plane or a plane equivalent to the (111) plane is preferably formed as the semiconductor film.

In the above, a substrate having an off-angle is preferably used as the single crystal substrate. Furthermore, the off-angle is preferably greater than 0° and less than or equal to 10°. Furthermore, the direction of the off-angle is preferably parallel to the [−2110] orientation of the single crystal substrate or an orientation equivalent to the [−2110] orientation.

With one embodiment of the present invention, a semiconductor device using a high-quality semiconductor film can be provided. A semiconductor device using a single crystal oxide semiconductor film can be provided. A high-performance semiconductor device can be provided. A semiconductor device with favorable electrical characteristics can be provided. A highly reliable semiconductor device can be provided. A low-power semiconductor device can be provided.

With one embodiment of the present invention, a semiconductor device having a novel structure can be provided. With one embodiment of the present invention, at least one of problems in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

In the accompanying drawings:

FIGS. 1A and 1B illustrate crystal plane matching;

FIGS. 2A and 2B illustrate crystal plane matching;

FIG. 3A illustrates a structure example of a semiconductor film, and FIGS. 3B to 3D illustrate the crystallinity of a substrate;

FIGS. 4A to 4D illustrate a structure example of a semiconductor device;

FIG. 5 illustrates a structure example of a semiconductor device;

FIGS. 6A to 6D illustrate a structure example of a semiconductor device;

FIG. 7 illustrates a structure example of a semiconductor device;

FIGS. 8A to 8D illustrate a structure example of a semiconductor device;

FIGS. 9A to 9D illustrate a structure example of a semiconductor device;

FIGS. 10A and 10B each illustrate a structure example of a semiconductor device;

FIGS. 11A to 11F illustrate structure examples of a semiconductor device;

FIGS. 12A1 to 12D2 illustrate a method for manufacturing a semiconductor device;

FIGS. 13A1 to 13D2 illustrate a method for manufacturing a semiconductor device;

FIGS. 14A1 to 14D2 illustrate a method for manufacturing a semiconductor device;

FIGS. 15A1 to 15C2 illustrate a method for manufacturing a semiconductor device;

FIGS. 16A and 16B show the dependence of Hall mobility on carrier concentration, and FIG. 16C is a cross-sectional view illustrating an indium oxide film;

FIG. 17 illustrates a structure example of a memory device;

FIGS. 18A and 18B illustrate a structure example of a memory device;

FIGS. 19A to 19D illustrate a structure example of a memory device;

FIG. 20 illustrates a structure example of a memory device;

FIGS. 21A and 21B illustrate a structure example of a display device;

FIG. 22 illustrates a structure example of a display device;

FIGS. 23A and 23B illustrate a structure example of a semiconductor device;

FIG. 24 illustrates a structure example of a semiconductor device;

FIGS. 25A to 25D illustrate structure examples of electronic apparatuses;

FIGS. 26A to 26F illustrate structure examples of electronic apparatuses;

FIGS. 27A to 27G illustrate structure examples of electronic apparatuses;

FIGS. 28A and 28B illustrate structure examples of electronic components; and

FIGS. 29A to 29C illustrate a structure example of a large computer.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of a current or a voltage, a switching operation for controlling conduction or non-conduction, and the like. A transistor in this specification includes, in its category, an insulated-gate field effect transistor (IGFET) and a thin film transistor (TFT).

The functions of a “source” and a “drain” are sometimes replaced with each other when a transistor of different polarity is used or when the direction of current flow is changed in a circuit operation, for example. Thus, the terms “source” and “drain” can be used interchangeably in this specification.

In this specification and the like, the expression “electrically connected” includes the case where components are connected through an “object having any electric function”. There is no particular limitation on the “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Note that in this specification and the like, “electrical connection” does not include the case where two nodes are connected to each other with an insulator (e.g., a dielectric of a capacitor, a gate insulating film of a transistor, or an interlayer insulating film) provided between the two nodes.

In this specification and the like, the expression “having substantially the same top surface shapes” means that the outlines of stacked layers at least partly overlap with each other. For example, the case of patterning an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (formation order) of a stacked body or the like, even in the case where a surface on which the stacked body is provided (e.g., a formation surface, a support surface, a bonding surface, or a planarization surface) is positioned over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

Unless otherwise specified, an off-state current in this specification and the like refers to a drain current of a transistor in an off state (also referred to as a non-conduction state or a cutoff state). Unless otherwise specified, the off state of an n-channel transistor means that gate-source voltage Vgs is lower than threshold voltage Vth, and the off state of a p-channel transistor means that Vgs is higher than Vth.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual orientation that shows an orientation in crystal is expressed with “[ ]”, a set orientation that shows all of the equivalent orientations is expressed with “< >”, an individual plane that shows a crystal plane is expressed with “( )”, and a set plane having equivalent symmetry is expressed with “{ }”.

### Embodiment 1

Described in this embodiment is a method for manufacturing a semiconductor film of one embodiment of the present invention.

One embodiment of the present invention relates to a method for forming a metal oxide film including a single crystal region on a single crystal substrate. According to one embodiment of the present invention, a metal oxide film having a single crystal structure or a metal oxide film having a substantially single crystal structure can be used in a channel formation region of a transistor, enabling the transistor to have both high reliability and excellent electrical characteristics.

An oxide containing indium, zinc, tin, or the like is preferably used as the metal oxide. It is particularly preferable to use a metal oxide that is easily crystallized. For example, indium oxide is easily crystallized at low temperatures and thus is preferably used, in which case a single crystal film with favorable crystallinity can be obtained. A transistor including single crystal or polycrystal indium oxide is preferable because it exhibits extremely high reliability.

For example, in the case where an oxide film with the cubic crystal system such as an indium oxide film is used as a semiconductor film, a single crystal substrate with the cubic crystal system is preferably used as the single crystal substrate. For example, it is preferable to use a single crystal substrate with the cubic crystal system, such as an yttria-stabilized zirconia (YSZ) substrate, a zirconium oxide substrate, or a silicon substrate. Alternatively, a semiconductor film having a single crystal structure with the cubic crystal system can be formed using a single crystal substrate with the tetragonal crystal system. Note that the material and the crystal structure of the single crystal substrate can be selected as appropriate in accordance with the crystal structure of the target semiconductor film. For example, a single crystal substrate of silicon carbide, gallium nitride, gallium oxide, or the like can also be used. Even when the single crystal substrate and a target semiconductor film have different crystal structures, epitaxial growth can sometimes be achieved by providing a buffer layer for alleviating distortion therebetween.

The absolute value of the lattice mismatch degree between a single crystal substrate and a semiconductor film is preferably as small as possible. In the case where epitaxial growth of a thin film occurs on a substrate, the lattice mismatch degree corresponds to a value obtained by dividing the difference between the length of a unit lattice vector of the substrate and the length of a unit lattice vector of the thin film by the length of the unit lattice vector of the substrate. A lattice constant can be used instead of the unit lattice vector. For example, in the case where the substrate and the thin film have the same crystal structure, the lattice mismatch degree can be a value obtained by dividing the difference between two lattice constants by the lattice constant of the substrate.

The lattice mismatch degree between the single crystal substrate and the semiconductor film is, for example, greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%. Here, the lattice mismatch degree has a positive value when the unit lattice vector of the thin film is larger than that of the substrate, and has a negative value when the unit lattice vector of the thin film is smaller than that of the substrate. Note that even in the case of a combination of a single crystal substrate and a semiconductor film with a large lattice mismatch degree, epitaxial growth can sometimes be achieved by providing the aforementioned buffer layer and increasing the thickness thereof. In that case, the lattice mismatch degree between the single crystal substrate and the semiconductor film can be less than −5% and greater than 5%. For example, the lattice mismatch degree between the single crystal substrate and the semiconductor film may be greater than or equal to −20% and less than or equal to 20%, greater than or equal to −15% and less than or equal to 15%, or greater than or equal to −10% and less than or equal to 10%.

For example, indium oxide with a cubic crystal structure (a bixbyite structure) has a lattice constant of 1.0117 nm (see Inorganic Crystal Structure Database (ICSD) coll. code. 14387). Meanwhile, YSZ (Zr_{0.9}Y_{0.1}O_{1.95}) with a cubic crystal structure (a fluorite crystal structure) has a lattice constant of 0.51481 nm (see ICSD coll. code. 248790). Thus, the lattice mismatch degree of a crystal grain included in an indium oxide film with respect to a crystal grain included in YSZ is −1.74%. Here, the content of yttrium included in YSZ can be higher than or equal to 2 atomic % and lower than or equal to 15 atomic %, preferably higher than or equal to 5 atomic % and lower than or equal to 10 atomic %.

In particular, an aluminum oxide substrate (also referred to as a sapphire substrate, a sapphire glass substrate, or the like) is preferably used as the single crystal substrate. The sapphire substrate is easily increased in area as compared with a YSZ substrate or the like, and can be processed in a conventional manufacturing line for semiconductor devices using a silicon wafer. The increased substrate area can reduce manufacturing costs of semiconductor devices using the semiconductor film of one embodiment of the present invention.

Aluminum oxide (Al₂O₃) crystal has a corundum crystal structure, which belongs to the hexagonal (or trigonal) crystal system. Since the (0001) plane in the hexagonal crystal system and the (111) plane in the cubic crystal system have similar atomic arrangements, epitaxial growth is likely to occur therebetween.

As described above, epitaxial growth sometimes occurs even between different crystal structures. For epitaxial growth, it is important to consider the crystal plane matching between a substrate and a formed film.

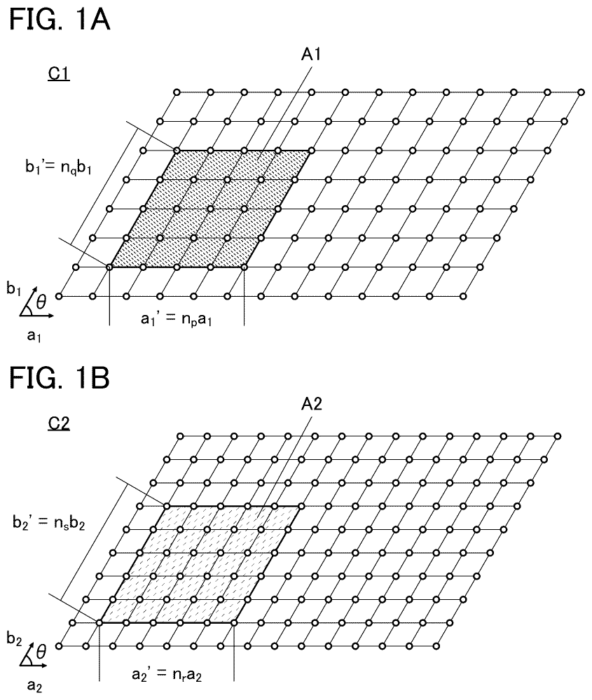

FIGS. 1A and 1B illustrate examples of atomic arrangement of a crystal plane of each of different crystals (a crystal C1 and a crystal C2). In each of the crystals C1 and C2, atoms indicated by white circles are periodically arranged in a two-dimensional manner. The atomic arrangement can be represented by two unit vectors.

The two unit vectors of the crystal C1 illustrated in FIG. 1A have lengths of a₁ and b₁ and an interior angle of θ. The two unit vectors of the crystal C2 illustrated in FIG. 1B have lengths of a₂ and b₂ and an interior angle of θ, which is the same as the interior angle of the unit vectors of the crystal C1.

In the crystal C1, a region A1 represents an area obtained by multiplying a unit cell, which is defined by two unit vectors, by an integer in the directions of the two unit vectors. Lengths a₁ and b1′ of two sides of the region A1 are respectively a₁′=nₚa₁ and b₁′=n_{q}b₁ (nₚ and n_{q} are each independently a natural number). Here, an area S1 of the region A1 is a₁′×b₁′× sin(θ).

Similarly, lengths a₂′ and b2′ of two sides of a region A2 in the crystal C2 are respectively a₂′=nᵣa₂ and b₂′=nₛb₂ (nᵣ and nₛ are each independently a natural number). An area S2 of the region A2 is a₂′×b₂′× sin(θ).

Here, there are combinations where a smallest value is obtained by a difference Δa between a₁′ and a₂′, a difference Δb between b₁′ and b₂′, and a difference ΔS between S1 and S2. Smaller values of these differences mean that the bonding surfaces of two crystals match well each other (have a high match degree).

A value corresponding to the above lattice mismatch degree can be calculated using the difference Δa between a₁′ and a₂′ (or the difference Δb between b₁′ and b₂′). As shown above, in consideration of epitaxial growth between different crystal structures (crystal systems), a lattice mismatch degree needs to be understood in a broad sense in consideration not only a difference between lattice constants but also a “superlattice” whose unit is an integer multiple of a unit lattice vector. In the case of FIGS. 1A and 1B, a lattice with the region A1 or the region A2 as a unit cell can be referred to as a “superlattice”; thus, the lattice mismatch degree in that case can also be referred to as “superlattice mismatch degree” to be distinguished from the above lattice mismatch degree. The superlattice mismatch degree is included in the lattice mismatch degree in a broad sense.

The superlattice mismatch degree corresponds to a value obtained by dividing the difference (i.e., Δa or Δb) between the length of a superlattice vector of a substrate (a₁′ or b₁′ in the above) and the length of a superlattice vector of a thin film (a₂′ or b₂′) by the length of the superlattice vector of the substrate (a₁′ or b₁′).

In the case where the crystal C2 is formed on the crystal C1, the area S1 of the region A1 in the crystal C1 serving as the substrate can be referred to as a “cross-sectional area”. For epitaxial growth of the crystal C2 on the crystal C1, it is important to reduce not only the above lattice mismatch degree but also the cross-sectional area of the crystal C1.

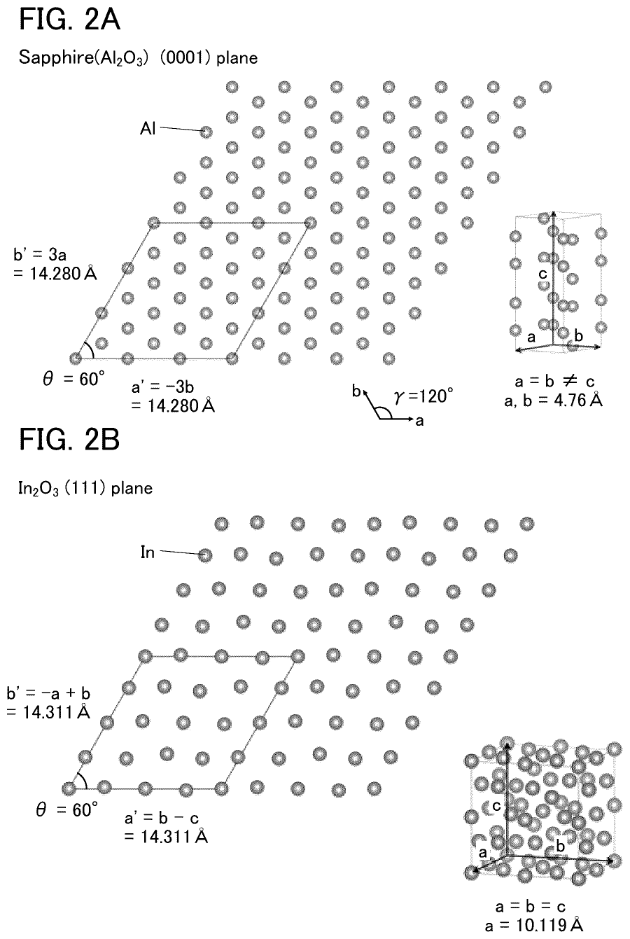

FIG. 2A illustrates a crystal structure of the (0001) plane of sapphire (Al₂O₃), which belongs to the hexagonal crystal system, and a crystal structure of a unit lattice on the right (see ICSD coll. code. 9770). FIG. 2B illustrates a crystal structure of the (111) plane of indium oxide (In₂O₃), which belongs to the cubic crystal system, and a crystal structure of a unit lattice on the right (see ICSD coll. code. 50846). In each of FIGS. 2A and 2B, the unit cell of a superlattice that has the smallest lattice mismatch degree and cross-sectional area is surrounded by a solid line. Each of FIGS. 2A and 2B also illustrates the values of lengths a′ and b′ of two sides of the unit cell.

From FIGS. 2A and 2B, the lattice mismatch degree between the (0001) plane of sapphire and the (111) plane of indium oxide is 0.22%, and the cross-sectional area at this time is 1.766 [nm²]. This result suggests that the combination of the (0001) plane of sapphire and the (111) plane of indium oxide exhibits higher matching than the combination of the (111) plane of YSZ and the (111) plane of indium oxide.

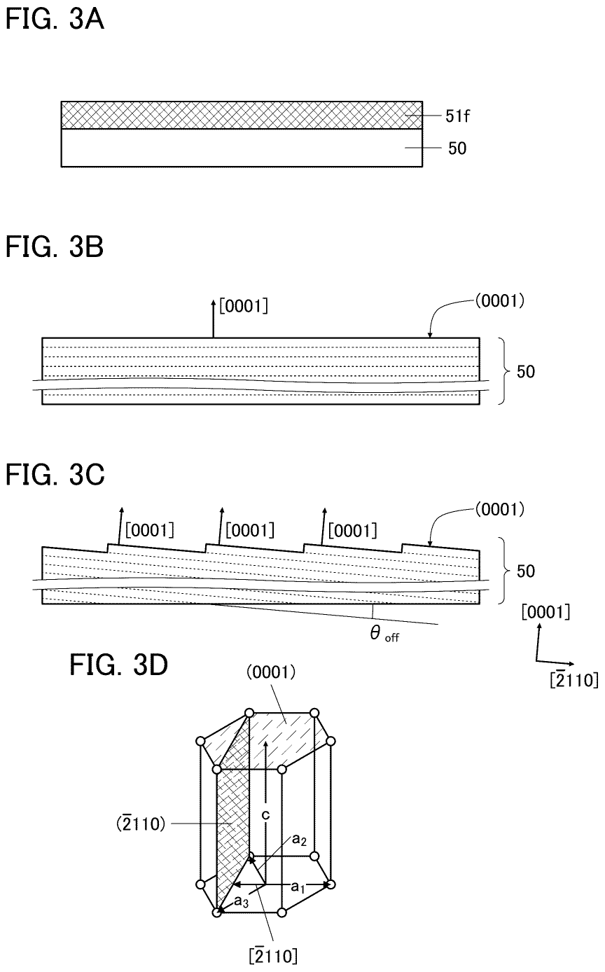

FIG. 3A is a schematic cross-sectional view of a semiconductor film 51f formed over a substrate 50.

The single crystal substrate described above can be used as the substrate 50. The substrate 50 can be formed using a material that has a small lattice mismatch degree with the semiconductor film 51f. The semiconductor film 51f can be used for a semiconductor layer of the semiconductor device of one embodiment of the present invention.

An indium oxide film is preferably used as the semiconductor film 51f. Note that the material for the semiconductor film 51f is not limited to indium oxide and can be a metal oxide film containing one or more of indium, tin, gallium, and zinc as its main component. Here, the main component refers to an element that has a proportion of higher than or equal to 0.1% in the total number of atoms of metal elements contained in the metal oxide. An element that has a proportion of lower than 0.1% is referred to as an impurity in some cases.

Note that the crystal structures of the substrate 50 and the semiconductor film 51f do not necessarily have the same crystal orientation in some cases. For example, a substrate including a crystal with a hexagonal crystal structure or a trigonal crystal structure can be provided below indium oxide including a crystal with a cubic crystal structure. For example, when the surface of the substrate 50 has the crystal orientation [001], epitaxial growth can sometimes occur such that the bottom surface of the semiconductor film 51f has the crystal orientation [111]. Examples of the hexagonal or trigonal crystal structure include a wurtzite structure, a corundum structure, a YbFe₂O₄-type structure, a Yb₂Fe₃O₇-type structure, and variations of these structures. An example of the crystal having a YbFe₂O₄-type structure or a Yb₂Fe₃O₇-type structure is In—Ga—Zn oxide (IGZO).

FIG. 3B is an enlarged view of the substrate 50 that is a sapphire substrate having a corundum structure. A single crystal substrate having the (0001) plane on the surface is preferably used as the substrate 50. In that case, the crystal orientation [0001] is perpendicular to the surface of the substrate. Here, four indices are used as the Miller index of the hexagonal crystal system.

In this specification and the like, the crystal plane is not limited to a specific plane even when denoted by an individual plane sign (e.g., (111) plane and (0001) plane), and includes the plane denoted by the sign and a plane equivalent thereto. Similarly, the crystal orientation is not limited to a specific orientation even when denoted by an individual orientation sign (e.g., [111] orientation and [−2110] orientation), and includes the orientation denoted by the sign and an orientation equivalent thereto.

FIG. 3C illustrates an example of the substrate 50 having an off-angle. When the substrate 50 having an off-angle is used as the substrate 50, a step structure is formed on the surface of the substrate 50, which promises to improve surface planarity due to a step-flow growth of a film to be formed, easily control the crystal orientation of the film to be formed, and the like. The use of the substrate 50 having an off-angle can inhibit polycrystallization of the film to be formed in some cases.

As illustrated in FIG. 3C, a periodic step structure is formed on the surface of the substrate 50 having an off-angle. At this time, the crystal orientation [0001] is inclined by an off-angle θ_{off} in the thickness direction of the substrate 50. Similarly, the crystal plane (0001) is inclined by an off-angle θ_{off} in the direction perpendicular to the thickness direction of the substrate 50.

In the case where a single crystal substrate having a hexagonal crystal structure is used as the substrate 50, the off-angle is preferably in a direction parallel to the <−2110> orientation. FIG. 3D schematically illustrates a unit lattice of the hexagonal crystal system. In the drawing, the a₁-axis, the a₂-axis, and the a₃-axis are equivalent to one another, and the interior angle between the two axes is 120°. The c-axis is perpendicular to each of the a₁-axis, the a₂-axis, and the a₃-axis. Here, the [−2110] orientation is parallel to the a₁-axis. The crystal plane (−2110), which is perpendicular to the a₁-axis, is what is called the a-plane. In other words, the off-angle is preferably parallel to the a-axis of the hexagonal crystal system (i.e., any one of the a₁-axis, the a₂-axis, and the a₃-axis). In that case, a periodic step structure can be formed on the substrate 50, which increases the crystallinity of a film to be formed.

In the case where a sapphire substrate is used as the substrate 50 and an indium oxide film is used as the semiconductor film 51f, the off-angle θ_{off} of the substrate 50 can be greater than 0° and less than or equal to 10°, preferably greater than 0° and less than or equal to 8°, further preferably greater than 0° and less than or equal to 6°. Typically, the substrate 50 processed to have an off-angle θ_{off} of 5° is preferably used.

Here, FIG. 3B corresponds to the case where the off-angle is 0°. The substrate 50 does not necessarily have an off-angle. Depending on the combination of the crystal structures of the substrate 50 and the semiconductor film 51f, the semiconductor film 51f can have higher crystallinity in some cases when the substrate does not have an off-angle (=0°). In particular, it is preferable that the substrate not have an off-angle when a combination of a YSZ substrate and an indium oxide film, which have the same crystal system (the cubic crystal system in this case) is used, for example. The substrate 50 that does not have an off-angle can be manufactured with lower costs (processing costs).

Next, a method for forming the semiconductor film 51f over the substrate 50 is described.

The semiconductor film 51f is formed over the substrate 50. The semiconductor film 51f can be formed by an atomic layer deposition (ALD) method, a sputtering method, a chemical vapor deposition (CVD) method, a pulsed laser deposition (PLD) method, a molecular beam epitaxy (MBE) method, a wet process, or the like. In particular, the semiconductor film 51f is preferably formed by an ALD method or a sputtering method.

The semiconductor film 51f is preferably formed by an ALD method. Generation of a crystal nucleus in a film can be inhibited by an ALD method for fixing each atom, rather than by a sputtering method in which particles are made to collide with the formation surface. Thus, unintentional polycrystallization of the semiconductor film 51f can be inhibited.

The semiconductor film 51f can be formed by an ALD method using a precursor and an oxidizer, for example. In the case where a film containing indium is formed as the semiconductor film 51f, a precursor containing indium can be used. In the case where a precursor containing indium is used, a thermal ALD method is preferably used as the ALD method. Alternatively, a plasma enhanced ALD (PEALD) method using plasma can be used.

As the precursor containing indium, trimethylindium, triethylindium, ethyldimethylindium, tris(1-methylethyl)indium, tris(2,2,6,6-tetramethyl-3,5-heptanedionato)indium, cyclopentadienylindium, indium(III) acetylacetonate, (3-(dimethylamino)propyl)dimethylindium, (diethylphosphino)dimethylindium, chlorodimethylindium, bromodimethylindium, dimethyl(2-propanolato)indium, or the like can be used.

As the precursor containing indium, an inorganic precursor not containing hydrocarbon may be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide). The decomposition temperature of indium trichloride is approximately higher than or equal to 500° C. and lower than or equal to 700° C. Thus, with the use of indium trichloride, film formation can be performed by an ALD method while heating is performed so that a substrate temperature becomes approximately higher than or equal to 400° C. and lower than or equal to 600° C., e.g., 500° C.

In the method for forming the semiconductor film 51f, it is preferable to use a material with a low impurity concentration. In other words, a high-purity material is preferably used in the method for forming the semiconductor film 51f. For example, the purity of the material is preferably higher than or equal to 3N (99.9%), further preferably higher than or equal to 4N (99.99%), further preferably higher than or equal to 5N (99.999%), still further preferably higher than or equal to 6N (99.9999%). The use of the high-purity material can reduce impurities in the semiconductor film 51f.

The gallium content and the aluminum content in the precursor containing indium are each preferably less than or equal to 1000 ppm, further preferably less than or equal to 500 ppm, further preferably less than or equal to 100 ppm, further preferably less than or equal to 50 ppm, further preferably less than or equal to 10 ppm, still further preferably less than or equal to 1 ppm. A reduced concentration of gallium in the semiconductor film 51f can increase the reliability of the transistor. A reduced concentration of aluminum in the semiconductor film 51f can increase the crystallinity of the semiconductor film 51f. Even in the case where the semiconductor film 51f containing gallium or aluminum as its main component is formed, a high-purity precursor containing indium is preferably used to reduce a variation in composition.

As the oxidizer, any one or two or more of ozone (O₃), oxygen (O₂), water (H₂O), nitrogen dioxide (NO₂), dinitrogen monoxide (N₂O), and hydrogen peroxide (H₂O₂) can be used, for example.

In the case where a single crystal or a polycrystal having a large particle diameter is formed, an oxidizer containing hydrogen, e.g., H₂O or H₂O₂, is preferably used in order to inhibit generation of a crystal nucleus in initial deposition. When a film with a small number of crystal nuclei is formed and then crystal growth is performed with heat applied during deposition or by heat treatment after deposition, a single crystal film or a polycrystal film with a large particle diameter can be formed. Meanwhile, in the case where the hydrogen concentration and the nitrogen concentration in the film are reduced, O₂ or O₃ is preferably used as the oxidizer; in particular, O₃ is further preferably used.

As an example of a method for controlling the composition of a film to be formed, adjusting the flow rate ratio, flowing time, flowing order, or the like of the source gases is given. By adjusting such conditions, a film whose composition is gradually changed can be formed. Furthermore, two or more films having different compositions can be formed successively.

The substrate temperature at the time of introducing the precursor into a reaction chamber is preferably a temperature corresponding to the decomposition temperature of the precursor. In the case of a thermal ALD method in which triethylindium is used as the precursor containing indium, the substrate temperature can be higher than or equal to 100° C. and lower than or equal to 350° C., preferably higher than or equal to 150° C. and lower than or equal to 300° C., for example.

In formation of the semiconductor film 51f, epitaxial growth (heteroepitaxial growth here) occurs in a region in contact with the substrate 50, so that a single crystal film in which the crystal orientation [111] is aligned in the direction parallel to the thickness direction of the substrate 50 can be formed. Crystallization of the semiconductor film 51f can occur not only in the formation of the semiconductor film 51f but also in cooling after the film formation or treatment involving substrate heating after the formation of the semiconductor film 51f (e.g., deposition treatment or heat treatment).

As described above, the semiconductor film 51f having a single crystal structure can be formed by using the substrate 50 that has an optimal crystal orientation in accordance with the crystal structure that the semiconductor film 51f can have.

Heat treatment is preferably performed after the formation of the semiconductor film 51f. Even when the semiconductor film 51f is not sufficiently crystallized in the formation, the crystallinity of the semiconductor film 51f can be improved by the heat treatment.

The heat treatment is performed in a nitrogen gas atmosphere, an inert gas (e.g., noble gas) atmosphere, or an atmosphere containing an oxidizing gas at 10 ppm (0.001%) or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment can be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above-described heat treatment is preferably less than or equal to 1 ppb (1×10⁻³ ppm), further preferably less than or equal to 0.1 ppb, still further preferably less than or equal to 0.05 ppb. The heat treatment using a highly purified gas can prevent entry of moisture or the like into the semiconductor film 51f as much as possible.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. A GRTA apparatus is an apparatus for heat treatment using a high-temperature gas.

Note that the semiconductor film 51f can also be formed by a sputtering method, a CVD method, an MBE method, or a PLD method. For example, in the case where the semiconductor film 51f is formed by a sputtering method, a sputtering gas containing hydrogen (H₂) is preferably used. Hydrogen is introduced when the semiconductor film 51f is formed by a sputtering method, whereby the semiconductor film 51f with low crystallinity can be formed. In addition, generation of a crystal nucleus can be inhibited or disappearance of a crystal nucleus can be promoted at the time of forming the semiconductor film 51f Note that as a sputtering gas, a single gas of a noble gas (typically argon), a single gas of oxygen, a mixed gas of a noble gas and oxygen, or the like can also be used.

Heat treatment is preferably performed after the semiconductor film 51f with low crystallinity is formed by a sputtering method. The heat treatment can be performed at higher than or equal to 250° C. and lower than or equal to 650° C., preferably higher than or equal to 300° C. and lower than or equal to 500° C., further preferably higher than or equal to 320° C. and lower than or equal to 450° C., for example. The heat treatment can promote crystal growth and increase the crystal grain size in the semiconductor film 51f. Thus, the semiconductor film 51f having crystallinity can be formed. The heat treatment can reduce the amount of excess hydrogen in the semiconductor film 51f.

In the above manner, the semiconductor film 51f including a large-area single crystal region can be formed over the substrate 50 having a single crystal structure.

An unnecessary portion is removed by etching after the formation of the semiconductor film 51f, so that an island-shaped semiconductor layer can be formed. Note that the above-described heat treatment may be performed after the island-shaped semiconductor layer is formed. When the island-shaped semiconductor layer is used for the channel formation region of the transistor, the transistor can have extremely favorable electrical characteristics and high reliability.

At least part of this embodiment can be implemented as appropriate in combination with any of the other embodiments described in this specification.

### Embodiment 2

Described in this embodiment are structure examples of the semiconductor device of one embodiment of the present invention and a manufacturing method example thereof. Here, a transistor is described as an example of the semiconductor device. The semiconductor film shown in Embodiment 1 can be used for a semiconductor layer of the transistor shown below.

### Structure Example 1

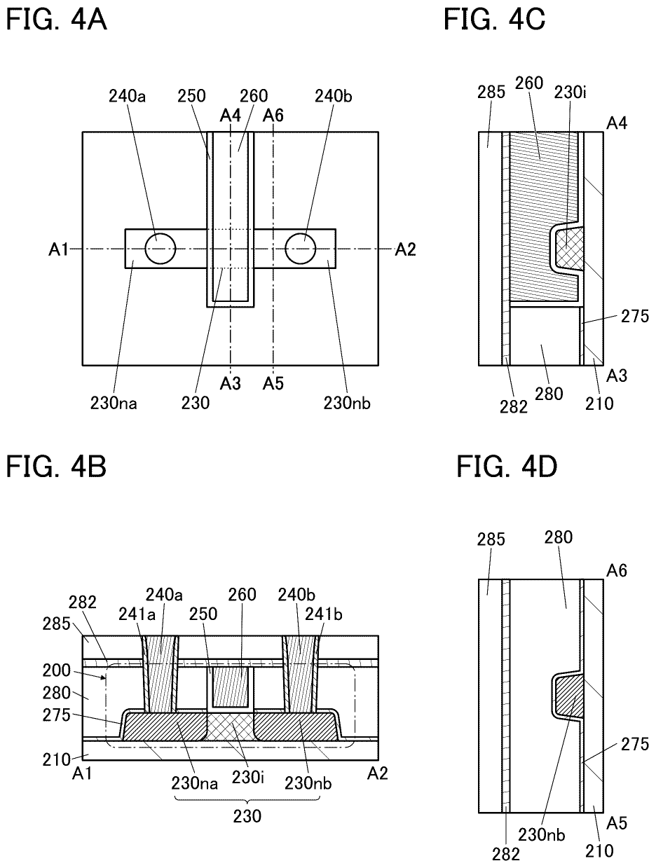

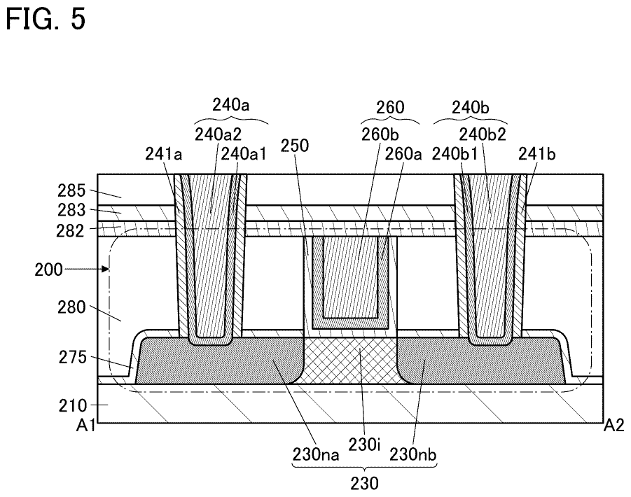

FIGS. 4A to 4D are a top view and cross-sectional views of a transistor 200. FIG. 4A is a top view of the transistor 200, and FIGS. 4B to 4D are schematic cross-sectional views respectively corresponding to cutting lines A1-A2, A3-A4, and A5-A6 in FIG. 4A. FIG. 4B corresponds to a cross section of the transistor 200 in a channel length direction, and FIGS. 4C and 4D each correspond to a cross section of the transistor 200 in a channel width direction. FIG. 5 is an enlarged view of FIG. 4B. Note that some components are omitted in FIG. 4A.

The transistor 200 is provided over a substrate 210. The transistor 200 includes a semiconductor layer 230 provided over the substrate 210, an insulating layer 250 over the semiconductor layer 230, and a conductive layer 260 over the insulating layer 250. An insulating layer 275 is provided to cover the semiconductor layer 230, and an insulating layer 280 is provided over the insulating layer 275. A groove portion reaching the semiconductor layer 230 is provided in the insulating layer 280 and the insulating layer 275, and the insulating layer 250 and the conductive layer 260 are provided in the groove portion. The insulating layer 250 is provided along the surfaces of the insulating layer 280, the insulating layer 275, and the semiconductor layer 230 in the groove portion. The conductive layer 260 is provided over the insulating layer 250 to fill the groove portion. An insulating layer 282, an insulating layer 283, and an insulating layer 285 are provided in this order to cover the insulating layer 280, the insulating layer 250, and the conductive layer 260.

The semiconductor layer 230 includes a region 230i and a pair of low-resistance regions (a region 230na and a region 230nb) between which the region 230i is sandwiched. The region 230i functions as a channel formation region of the transistor 200. The region 230na functions as one of a source region and a drain region, and the region 230nb functions as the other of the source region and the drain region. The insulating layer 250 functions as a gate insulating layer of the transistor 200, and the conductive layer 260 functions as a gate electrode of the transistor 200.

The semiconductor film 51f shown in Embodiment 1 can be used as the semiconductor layer 230. The substrate 50 shown in Embodiment 1 can be used as the substrate 210.

For the semiconductor layer 230, a metal oxide functioning as a semiconductor (hereinafter also referred to as an oxide semiconductor) is preferably used.

The band gap of the metal oxide functioning as a semiconductor is preferably greater than or equal to 2 eV, further preferably greater than or equal to 2.5 eV. The use of such a metal oxide having a wide band gap can reduce the off-state current of the transistor. A transistor including a metal oxide in a channel formation region is referred to as an OS transistor. Since the OS transistor has a low off-state current, the power consumption of the semiconductor device can be sufficiently reduced. In addition, the OS transistor has high frequency characteristics, which enables the semiconductor device to operate at high speed.

Indium oxide is preferably used for the semiconductor layer 230. In particular, a single crystal indium oxide film is preferably used. Note that a film having crystallinity is preferably used for the semiconductor layer 230, and indium oxide having a single crystal structure is particularly preferably used; alternatively, indium oxide having a polycrystal structure or a microcrystal structure can be used. The use of indium oxide having a single crystal structure can inhibit carrier scattering or the like at the crystal grain boundary, thereby achieving a transistor having high field-effect mobility. In addition, the transistor can have high reliability.

In the case where indium oxide having a polycrystal structure is used, no crystal grain boundary is preferably observed at least in a channel formation region (a region overlapping with the conductive layer 260). In that case, indium oxide having a polycrystal structure can have an effect similar to that in the case of having a single crystal structure.

The thickness of each of the regions 230i, 230na, and 230nb is preferably greater than or equal to 2 nm and less than or equal to 50 nm, further preferably greater than or equal to 2.5 nm and less than or equal to 30 nm, further preferably greater than or equal to 2.5 nm and less than or equal to 20 nm, further preferably greater than or equal to 5 nm and less than or equal to 20 nm, still further preferably greater than or equal to 5 nm and less than or equal to 10 nm. When the thickness of the semiconductor layer 230 is within the above-described range, the crystallinity of the semiconductor layer 230 can be increased.

Among oxide semiconductors having high crystallinity, an indium oxide film is a film in which one or both of hydrogen and oxygen move easily as compared with, for example, an IGZO (In—Ga—Zn—O-based oxide) film. Thus, it can be said that one or both of hydrogen and oxygen are more likely to be supplied to and released from an indium oxide film than to/from an IGZO film, for example. In other words, excess oxygen or excess hydrogen, which might be carriers or fixed charges, is less likely to be accumulated in the semiconductor layer 230, so that the transistor can have favorable electrical characteristics and reliability.

In the semiconductor layer 230, the concentration of an element that reduces crystallinity is preferably reduced. For example, the concentration of an element such as boron or aluminum is preferably lower than or equal to 1 atomic %, further preferably lower than or equal to 0.1 atomic %, still further preferably lower than or equal to 0.01 atomic % (100 ppm).

In the case where the semiconductor layer 230 contains a large amount of gallium, the threshold voltage might change largely in a positive bias temperature stress (PBTS) test because gallium is likely to bond to excess oxygen atoms. Thus, the concentration of gallium in the semiconductor layer 230 is preferably lower than or equal to 1 atomic %, further preferably lower than or equal to 0.1 atomic %, still further preferably lower than or equal to 0.01 atomic % (100 ppm).

Other examples of the metal oxide that can be used for the semiconductor layer 230 include tin oxide, zinc oxide, indium tin oxide, indium titanium oxide, indium gallium oxide, indium tungsten oxide, indium zinc oxide, indium gallium aluminum oxide, indium gallium tin oxide, gallium zinc oxide, aluminum zinc oxide, indium aluminum zinc oxide, indium tin zinc oxide, indium titanium zinc oxide, indium gallium zinc oxide, indium gallium tin zinc oxide, and indium gallium aluminum zinc oxide. Alternatively, indium tin oxide containing silicon, gallium tin oxide, aluminum tin oxide, or the like can also be used. A film including any of these materials preferably has at least crystallinity, further preferably a single crystal structure.

The semiconductor layer 230 may have a stacked-layer structure, e.g., a stacked-layer structure of two layers or three or more layers. In that case, at least one of the stacked films may contain an element different from that of the other film(s), or all of the stacked films may contain the same constituent elements.

For example, an indium oxide film can be used for one layer of a two-layer structure, and an oxide film containing one or more elements of tin, zinc, gallium, aluminum, tungsten, molybdenum, and silicon in addition to indium can be used for the other layer. For another example, an indium oxide film can be used for the second layer of a three-layer structure, and an oxide film containing one or more of the above elements in addition to indium can be used for each of the first and third layers.

Alternatively, an indium oxide film can be used for all of the films of the two-layer structure or the three-layer structure. In that case, at least one of the density, carrier concentration, band gap, hydrogen concentration in a film, concentration of impurities other than hydrogen in a film, amount of oxygen vacancy, and the like of one film of the stacked-layer structure can be different from that the other film(s). For example, when an indium oxide film used for each of the first and third layers of the three-layer structure has a wider band gap than an indium oxide film used for the second layer, what is called a buried channel structure can be achieved, offering a highly reliable transistor.

The regions 230na and 230nb have lower resistance than the region 230i. In other words, the regions 230na and 230nb have higher carrier concentration than the region 230i. The regions 230na and 230nb preferably contain an element that imparts conductivity to the semiconductor layer 230. Examples of the element include titanium, tantalum, tungsten, molybdenum, tin, silicon, germanium, zirconium, hafnium, antimony, magnesium, hydrogen, boron, and phosphorus. The regions 230na and 230nb preferably contain at least one of the above elements.

The above elements can be introduced into part of the semiconductor layer 230 by a doping method, an ion implantation method, a thermal diffusion method, or the like so as to impart conductivity thereto. At this time, the elements are preferably not introduced into the region 230i, which is to be a channel formation region. For example, the region 230i is covered with a mask and the above elements are introduced into a region of the semiconductor layer 230 that is not covered with the mask by a doping method or an ion implantation method, whereby the region 230i, the region 230na, and the region 230nb can be formed separately.

The insulating layer 250 functioning as a gate insulating layer preferably has a function of trapping and fixing hydrogen. This allows a reduction in the hydrogen concentration in the channel formation region in the semiconductor layer 230. As a result, an i-type or substantially i-type channel formation region can be obtained.

Here, the insulating layer 250 preferably has a stacked-layer structure of a first layer in contact with the semiconductor layer 230, a second layer over the first layer, and a third layer over the second layer. In that case, the first layer preferably has a function of capturing or fixing hydrogen.

An example of the insulator having a function of capturing or fixing hydrogen is a metal oxide having an amorphous structure. As the first layer, for example, a metal oxide, such as magnesium oxide or an oxide containing one or both of aluminum and hafnium, is preferably used. In such a metal oxide having an amorphous structure, an oxygen atom has a dangling bond with which hydrogen is captured or fixed in some cases. In other words, the metal oxide having an amorphous structure has high capability of capturing or fixing hydrogen.

A material with a high dielectric constant (a high-k material) is preferably used for the first layer. An example of the high-k material is an oxide containing one or both of aluminum and hafnium. With the use of the high-k material for the first layer, a gate potential applied during the operation of the transistor can be reduced while the physical thickness of the gate insulating layer is maintained. Furthermore, the equivalent oxide thickness of the insulator functioning as the gate insulating layer can be reduced.

For the first layer, it is preferable to use an oxide containing one or both of aluminum and hafnium, it is further preferable to use an oxide containing one or both of aluminum and hafnium and having an amorphous structure, and it is still further preferable to use aluminum oxide having an amorphous structure.

For the second layer, an insulator having thermal stability, such as silicon oxide or silicon oxynitride, is preferably used.

A fourth layer may be provided over the second layer. In that case, an insulator that can be used for the first layer can be provided as the fourth layer. For example, hafnium oxide can be used for the fourth layer. Here, the fourth layer provided between the third layer and the second layer enables hydrogen contained in the second layer or the like to be captured and fixed more effectively.

The third layer preferably has a barrier property against oxygen. The third layer is provided between the channel formation region in the semiconductor layer 230 and the conductive layer 260 and between the insulating layer 280 and the conductive layer 260. Such a structure can inhibit oxygen contained in the channel formation region in the semiconductor layer 230 from diffusing into the conductive layer 260 and thus can inhibit formation of oxygen vacancies in the channel formation region in the semiconductor layer 230. Oxygen contained in the semiconductor layer 230 and oxygen contained in the insulating layer 280 can be inhibited from diffusing into the conductive layer 260 and oxidizing the conductive layer 260. The third layer preferably has a lower oxygen-transmitting property than at least the insulating layer 280. A silicon nitride film is preferably used as the third layer, for example. In that case, the third layer is an insulator containing at least nitrogen and silicon.

Furthermore, the third layer preferably has a barrier property against hydrogen. This can prevent impurities such as hydrogen contained in the conductive layer 260 from diffusing into the semiconductor layer 230.

The insulating layer 275 preferably has a barrier property against oxygen. The insulating layer 275 is provided between the insulating layer 280 and the semiconductor layer 230. Such a structure can inhibit oxygen contained in the semiconductor layer 230 from diffusing into the insulating layer 280. As a result, formation of oxygen vacancies in the semiconductor layer 230 (particularly in the region 230i) can be inhibited. The insulating layer 275 preferably has a lower oxygen-transmitting property than at least the insulating layer 280. Furthermore, the insulating layer 275 preferably has a barrier property against hydrogen. This can inhibit hydrogen contained in the insulating layer 280 from diffusing into the semiconductor layer 230 and thus can inhibit the semiconductor layer 230 (particularly the region 230i) from becoming an n-type region.

For example, silicon nitride or silicon nitride oxide is preferably used for the insulating layer 275. In addition, aluminum oxide, hafnium oxide, magnesium oxide, gallium oxide, an oxide containing aluminum and hafnium (hafnium aluminate), an oxide containing hafnium and silicon (hafnium silicate), or the like can be used.

One or both of the insulating layers 282 and 283 function as a barrier film that prevents diffusion of impurities such as water and hydrogen from the outside to the insulating layer 280 side. A film having a barrier property against oxygen and hydrogen is preferably used for one or both of the insulating layers 282 and 283 like the insulating layer 275.

An insulating film that captures and fixes hydrogen is preferably used as one or both of the insulating layers 282 and 283. This can prevent diffusion of impurities such as water and hydrogen to the insulating layer 280 side more effectively. For the insulating film that captures and fixes hydrogen, a metal oxide such as magnesium oxide, aluminum oxide, hafnium oxide, hafnium aluminate, or hafnium silicate can be used, for example.

Opening portions reaching the regions 230na and 230nb are provided in the insulating layer 285, the insulating layer 283, the insulating layer 282, the insulating layer 280, and the insulating layer 275. An insulating layer 241a is provided in contact with a sidewall of the opening portion reaching the region 230na, and a conductive layer 240a is provided on the inner side of the insulating layer 241a. Similarly, an insulating layer 241b and a conductive layer 240b are provided in the opening portion reaching the region 230nb. The conductive layers 240a and 240b function as vias (also referred to as plugs) that connect a wiring or the like provided over the transistor 200 to a source or a drain of the transistor 200.

The conductive layers 240a and 240b are preferably formed using a conductive material containing tungsten, copper, or aluminum as its main component. The conductive layers 240a and 240b may each have a stacked-layer structure.

For example, as illustrated in FIG. 5, the conductive layers 240a and 240b may each have a two-layer structure. The conductive layer 240a includes a conductive layer 240a1 formed along the opening portion and a conductive layer 240a2 formed on the inner side of the conductive layer 240a1. Similarly, the conductive layer 240b includes a conductive layer 240b1 and a conductive layer 240b2.

For the conductive layers 240a1 and 240b1, a conductive material having a function of inhibiting passage of impurities such as water and hydrogen, such as tantalum, tantalum nitride, titanium, titanium nitride, ruthenium, or ruthenium oxide, is preferably used. The conductive layers 240a1 and 240b1 can inhibit entry of impurities such as water and hydrogen into the semiconductor layer 230 through the conductive layers 240a2 and 240b2. Note that the conductive layers 240a2 and 240b2 can be formed using any of the above-described conductive materials that can be used for the conductive layers 240a and 240b.

As illustrated in FIG. 5, the conductive layers 240a and 240b can be formed such that their top surfaces are level or substantially level with the top surface of the insulating layer 285. As illustrated in FIG. 5, the conductive layers 240a and 240b are sometimes formed such that their lower portions are embedded in the semiconductor layer 230.

The insulating layers 241a and 241b function as barrier films that prevent diffusion of water or hydrogen contained in the insulating layer 285, the insulating layer 280, or the like into the conductive layer 240a or the conductive layer 240b. The insulating layers 241a and 241b preferably have a function of preventing diffusion of oxygen from the insulating layer 285, the insulating layer 280, or the like into the conductive layer 240a or 240b and preventing oxidation of the conductive layer 240a or 240b. The insulating layers 241a and 241b can be formed using any of the materials that can be used for the insulating layer 275.

The conductive layer 260 functions as the gate electrode of the transistor 200. Here, the conductive layer 260 is preferably provided to extend in the channel width direction as illustrated in FIGS. 4A and 4C. With such a structure, the conductive layer 260 functions as a wiring when a plurality of transistors are provided.

The conductive layer 260 may have a stacked-layer structure. FIG. 5 illustrates an example in which the conductive layer 260 includes a conductive layer 260a positioned on the side in contact with the insulating layer 250 and a conductive layer 260b over the conductive layer 260a. In that case, the conductive layer 260a is preferably formed using a conductive material that is less likely to be oxidized, such as titanium, titanium nitride, tantalum, tantalum nitride, ruthenium, or ruthenium oxide, or a conductive material having a function of inhibiting diffusion of oxygen. The conductive layer 260b is preferably formed using a low-resistance conductive material such as tungsten, copper, or aluminum.

The insulating layers 280 and 285 function as interlayer insulating films and thus are preferably formed using an insulating material with a relatively low dielectric constant. The insulating layers 280 and 285 are preferably formed using silicon oxide, silicon oxynitride, silicon oxide to which fluorine is added, silicon oxide to which carbon is added, silicon oxide to which carbon and nitrogen are added, porous silicon oxide, or the like.

### Structure Example 2

Described below is a structural example partly different from Structural example 1 described above. Note that components similar to those described above are denoted by the same reference numerals as those described above and are not repeatedly described.

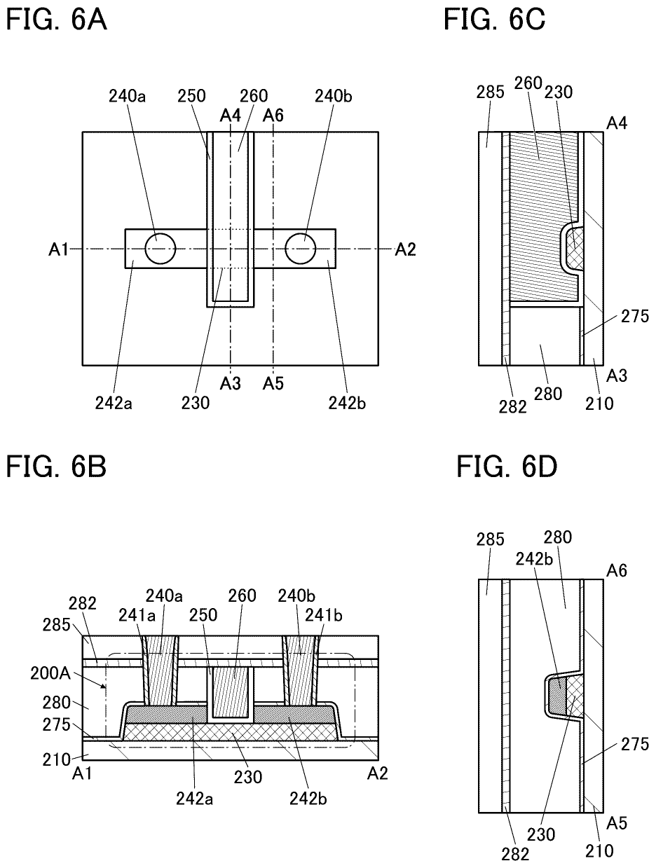

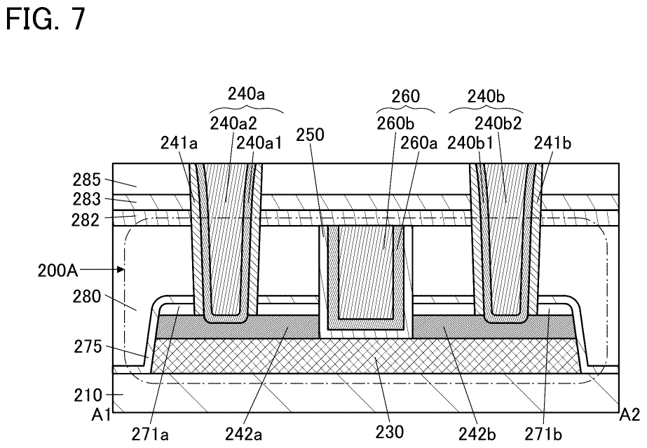

FIG. 6A is a top view of a transistor 200A shown below, and FIGS. 6B to 6D are cross-sectional views of the transistor 200A. FIG. 7 illustrates an enlarged view of FIG. 6B.

The transistor 200A is different from the transistor 200 shown in Structure example 1 above mainly in that a conductive layer 242a, a conductive layer 242b, an insulating layer 271a, and an insulating layer 271b are included, the region 230na and the region 230nb are not formed in the semiconductor layer 230, and the like.

The conductive layer 242a functions as one of a source electrode and a drain electrode of the transistor 200A and the conductive layer 242b functions as the other. The conductive layers 242a and 242b are provided over the semiconductor layer 230. The insulating layer 275 is provided to cover the conductive layers 242a and 242b. The insulating layer 250 is provided in contact with side surfaces of the conductive layers 242a and 242b.

The conductive layers 242a and 242b are preferably formed using a conductive material that is less likely to be oxidized, such as a metal oxide or a metal nitride. This can prevent excessive oxidation of the conductive layers 242a and 242b due to oxygen contained in the semiconductor layer 230 and prevent an increase in electric resistance.

The conductive layers 242a and 242b each preferably have a stacked-layer structure. In that case, the above-described conductive material that is less likely to be oxidized, such as a metal oxide or a metal nitride, is preferably used for a layer in contact with the semiconductor layer 230. A layer that is not in contact with the semiconductor layer 230 is preferably formed using a conductive material that contains a metal or an alloy having higher conductivity than that used for the layer in contact with the semiconductor layer 230. This enables the conductive layers 242a and 242b to function as a highly conductive wiring or electrode.

In the conductive layers 242a and 242b, a metal nitride is preferably used for the layer in contact with the semiconductor layer 230; for example, a nitride containing tantalum, a nitride containing titanium, a nitride containing molybdenum, a nitride containing tungsten, a nitride containing tantalum and aluminum, or a nitride containing titanium and aluminum is preferably used. A metal oxide is also preferably used; a metal oxide such as indium oxide containing tungsten oxide, indium oxide containing titanium oxide, indium tin oxide (ITO), indium tin oxide containing titanium oxide, indium tin oxide to which silicon is added (also referred to as ITSO), indium zinc oxide, or indium zinc oxide containing tungsten oxide can be used. Besides, ruthenium, ruthenium oxide, ruthenium nitride, an oxide containing strontium and ruthenium, an oxide containing lanthanum and nickel, or the like may be used. These materials are preferable because they are conductive materials that are less likely to be oxidized or materials that maintain their conductivity even after absorbing oxygen.

The insulating layer 271a is positioned between the conductive layer 242a and the insulating layer 275, and the insulating layer 271b is positioned between the conductive layer 242b and the insulating layer 275. The insulating layers 271a and 271b are inorganic insulators that function as an etching stopper at the time of processing the conductive layers 242a and 242b and protect the conductive layers 242a and 242b. Since the insulating layers 271a and 271b are respectively in contact with the conductive layers 242a and 242b, the insulating layers 271a and 271b are preferably inorganic insulators that are less likely to oxidize the conductive layers 242a and 242b. For example, it is possible to employ a structure in which the insulating layers 271a and 271b each have a stacked-layer structure, silicon nitride is used for a layer in contact with the conductive layers 242a and 242b, and silicon oxide is used for the other layer(s).

The conductive layers 240a and 240b are each positioned in an opening portion provided in the insulating layer 285, the insulating layer 283, the insulating layer 282, the insulating layer 280, the insulating layer 275, and the insulating layer 271a (or the insulating layer 271b). The conductive layers 240a1 and 240b1 are respectively provided in contact with the conductive layers 242a and 242b.

### Variation Examples

Described below are structure examples partly different from Structural examples 1 and 2 described above. Note that components similar to those described above are not described below.

### Variation Example 1

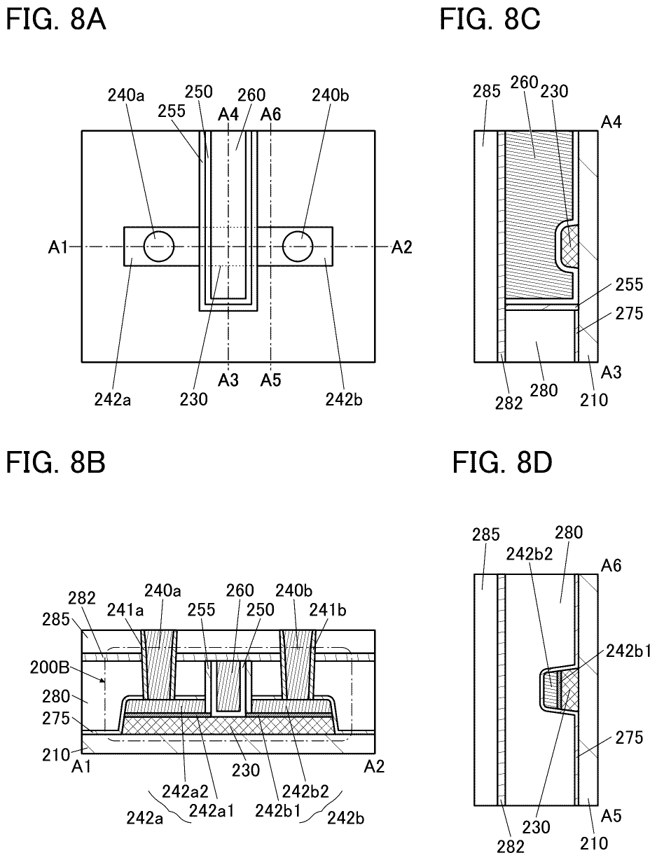

FIGS. 8A to 8D illustrate a structure example of a transistor 200B. FIG. 8A is a top view, and FIGS. 8B to 8D are cross-sectional views. The structure illustrated in FIGS. 8A to 8D is different from Structure example 2 mainly in that an insulating layer 255 is included. The insulating layer 250 is in contact with a side surface of the insulating layer 255.

Note that here, the conductive layers 242a and 242b each have a two-layer structure. The conductive layer 242a has a stacked-layer structure of a conductive layer 242a1 and a conductive layer 242a2 over the conductive layer 242a1. The conductive layer 242b has a stacked-layer structure of a conductive layer 242b1 and a conductive layer 242b2 over the conductive layer 242b1.

The insulating layer 255 is provided inside an opening portion formed in the insulating layer 280 and the like, and is in contact with the side surface of the insulating layer 280, the side surface of the conductive layer 242a2, the side surface of the conductive layer 242b2, the top surface of the conductive layer 242a1, the top surface of the conductive layer 242b1, and the top surface of the substrate 210 in the opening portion.

The insulating layer 255 preferably has a barrier property against oxygen. When the insulating layer 255 has a barrier property against oxygen, oxidation of the side surfaces of the conductive layers 242a and 242b can be inhibited and accordingly formation of oxide films on the side surfaces can be inhibited. It is thus possible to inhibit a reduction in the on-state current or field-effect mobility of the transistor 200. The insulating layer 255 can be formed using a barrier insulator that can be used for the insulating layer 275 and the like. For example, silicon nitride is used for the insulating layer 255.

The opening portion provided in the insulating layer 280 overlaps with a region between the conductive layers 242a2 and 242b2. In the top view, the side surfaces of the insulating layer 280 in the opening portion are aligned or substantially aligned with the side surfaces of the conductive layers 242a2 and 242b2. Parts of the conductive layers 242a1 and 242b1 are formed to extend to the inside of the opening portion. That is, the conductive layer 242a1 has a portion that extends beyond the conductive layer 242a2 toward the conductive layer 260. Similarly, the conductive layer 242b1 has a portion that extends beyond the conductive layer 242b2 toward the conductive layer 260.

The insulating layer 255 is provided in contact with the top surface of the extending portion of the conductive layer 242a1 and the top surface of the extending portion of the conductive layer 242b1. The insulating layer 250 is not in contact with the conductive layers 242a2 and 242b2 and is in contact with the top surface of the semiconductor layer 230, the side surface of the conductive layer 242a1, the side surface of the conductive layer 242b1, and the side surface of the insulating layer 255.

The insulating layer 255 is formed by anisotropic etching in a sidewall shape to be in contact with the sidewall of the opening portion provided in the insulating layer 280. The insulating layer 255 is formed in contact with the side surfaces of the conductive layers 242a2 and 242b2 and has a function of inhibiting oxidation of the conductive layers 242a2 and 242b2.

### Variation Example 2

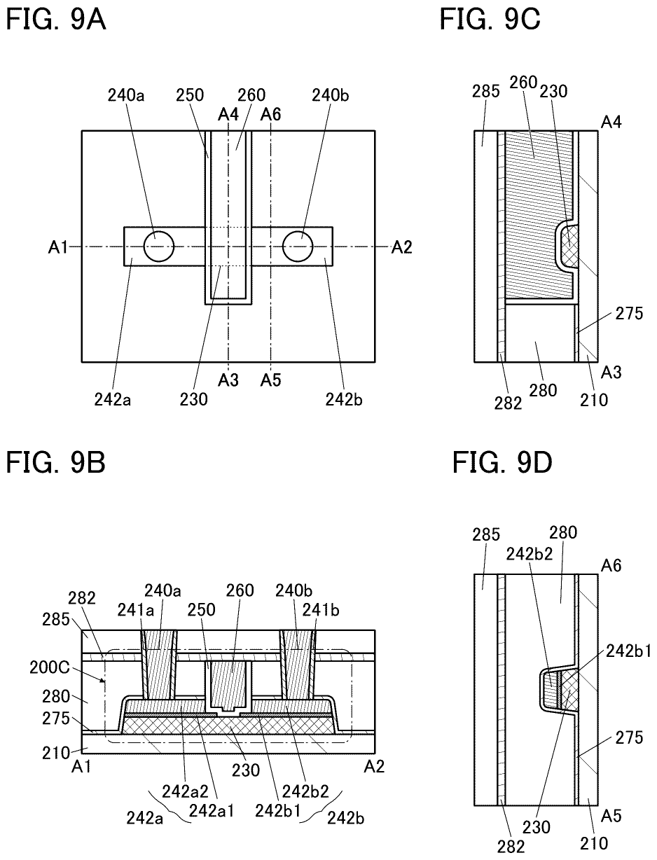

FIGS. 9A to 9D illustrate a structure example of a transistor 200C. The structure illustrated in FIGS. 9A to 9D is different from Variation example 1 mainly in that the insulating layer 255 is not included.

In the case where the insulating layer 255 is not provided, part of the insulating layer 250 is positioned to overlap with the extending portions of the conductive layers 242a1 and 242b1. In some cases, part of the conductive layer 260 is positioned to overlap with the extending portions of the conductive layers 242a1 and 242b1. Here, the extending portions of the conductive layers 242a1 and 242b1 are in contact with the insulating layer 250. The side surface of the insulating layer 250 is in contact with the side surfaces of the insulating layers 280, 275, 271a, and 271b and the side surfaces of the conductive layers 242a2 and 242b2.

A portion of the insulating layer 250 that is placed in an opening portion provided in the insulating layer 280 is formed to reflect the shape of the opening portion. Accordingly, the insulating layer 250 is formed to reflect the shapes of the conductive layers 242a1 and 242b1 that extend in the opening portion.

As illustrated in FIG. 9B, in the cross-sectional view of the transistor 200C in the channel length direction, the distance between the conductive layers 242a1 and 242b1 is smaller than the distance between the conductive layers 242a2 and 242b2. With this structure, the distance between the source and the drain can be shortened, and the channel length can be accordingly shortened. This can improve the frequency characteristics of the transistor 200C. In this manner, scaling down of the semiconductor device enables the semiconductor device to have a higher operating speed.

### Variation Example 3

In the above-described structure, the gate electrode is embedded; a transistor described below has a structure different from the above.

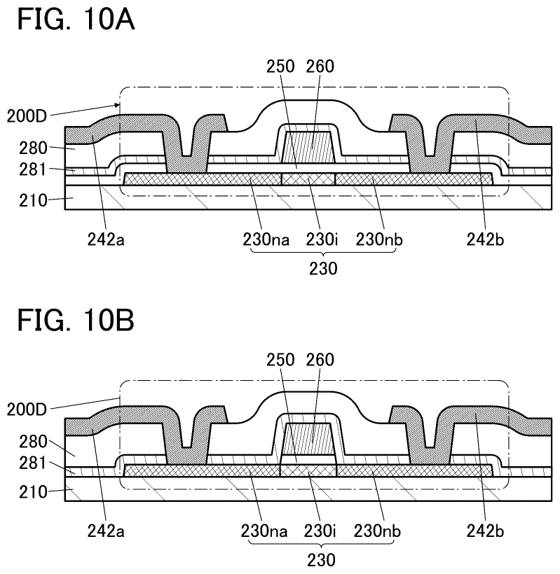

FIG. 10A is a cross-sectional view of a transistor 200D in the channel length direction. The transistor 200D includes the semiconductor layer 230, the insulating layer 250, the conductive layer 260, the conductive layer 242a, and the conductive layer 242b. The semiconductor layer 230 is in contact with the top surface of the substrate 210.

The insulating layer 250 is provided to cover the semiconductor layer 230, and the conductive layer 260 is provided in a position overlapping with the semiconductor layer 230 over the insulating layer 250. An insulating layer 281 and the insulating layer 280 are stacked to cover the insulating layer 250 and the conductive layer 260.

The semiconductor layer 230 includes the region 230i overlapping with the conductive layer 260 and a pair of regions 230na and 230nb between which the region 230i is sandwiched. The region 230i functions as a channel formation region and the regions 230na and 230nb are low-resistance regions.

A pair of opening portions each reaching the region 230na or the region 230nb are provided in the insulating layer 281, the insulating layer 280, and the insulating layer 250. The conductive layers 242a and 242b are provided over the insulating layer 280 and are respectively in contact with the regions 230na and 230nb in the opening portions.

The insulating layer 281 can be formed using an insulator having a barrier property against hydrogen and oxygen like the insulating layer 275 described above. This can inhibit diffusion of impurities contained in the insulating layer 280 into the semiconductor layer 230 and diffusion of oxygen contained in the semiconductor layer 230 to the insulating layer 280 side.

The regions 230na and 230nb preferably contain an element that imparts conductivity to the semiconductor layer 230. For example, with the use of the conductive layer 260 as a mask, the above element can be introduced into a region of the semiconductor layer 230 that does not overlap with the conductive layer 260 with the insulating layer 250 therebetween by a doping method or an ion implant method.

FIG. 10B illustrates an example in which the insulating layer 250 is positioned only in a region overlapping with the conductive layer 260 and is not provided over the regions 230na and 230nb of the semiconductor layer 230. In that case, when a film containing the above element is used as the insulating layer 281 in contact with the regions 230na and 230nb, the element can be introduced into the regions 230na and 230nb at the time of forming the insulating layer 281 or by heat treatment or the like performed later. For example, when silicon nitride containing hydrogen is used for the insulating layer 281, hydrogen can be supplied to the regions 230na and 230nb.

The above is the description of the variation examples.

### Application Example

An application example of the semiconductor device of one embodiment of the present invention is described below.

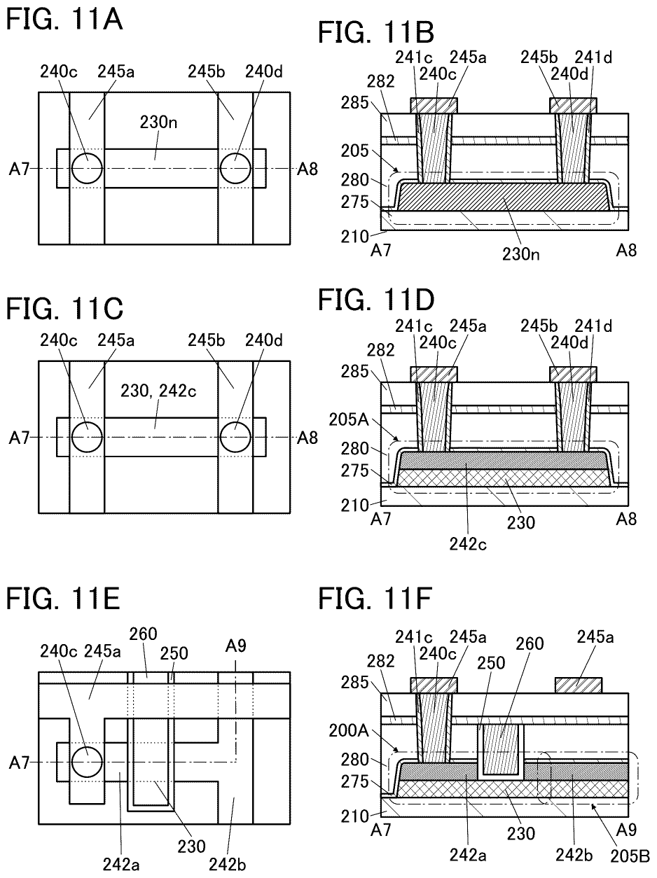

The region 230n (the region 230na or the region 230nb) included in the semiconductor layer 230 shown in Structure example 1 above can be used as a wiring, an electrode, a terminal, or the like. FIG. 11A is a top view of the case where the region 230n is used as a wiring, and FIG. 11B is a cross-sectional view taken along the cutting line A7-A8 in FIG. 11A.

A conductive layer 245a and a conductive layer 245b functioning as wirings are provided over the insulating layer 285. The region 230n functions as a wiring 205 for connecting the conductive layer 245a and the conductive layer 245b. The region 230n and the conductive layer 245a are connected by a conductive layer 240c, and the region 230n and the conductive layer 245b are connected by a conductive layer 240d. An insulating layer 241c is provided between the conductive layer 240c and the insulating layer 285 and the like, and an insulating layer 241d is provided between the conductive layer 240d and the insulating layer 285 and the like.

The stacked-layer structure of the semiconductor layer 230, the conductive layer 242a, and the like shown in Structure example 2 above can also be used as a wiring, an electrode, a terminal, or the like. A structure example of such a case is illustrated in FIGS. 11C and 11D. A wiring 205A includes a stack of the semiconductor layer 230 and a conductive layer 242c.

The conductive layer 242c and the conductive layer 245a are connected by the conductive layer 240c, and the conductive layer 242c and the conductive layer 245b are connected by the conductive layer 240d. Since the semiconductor layer 230 and the conductive layer 242c are stacked in the wiring 205A, the stack can be used as the wiring and the like even when an element for imparting conductivity is not added to the semiconductor layer 230.

FIGS. 11E and 11F illustrate an example in which part of the transistor 200A is used as a wiring 205B. FIG. 11E is a top view, and FIG. 11F is a cross-sectional view taken along the cutting line A7-A9 in FIG. 11E.

The conductive layer 242a included in the transistor 200A is connected to the conductive layer 245a over the insulating layer 285 through the conductive layer 240c. Meanwhile, the stack of the conductive layer 242b and the semiconductor layer 230 positioned on the opposite side with the conductive layer 260 therebetween is part of the transistor 200A and is also part of the wiring 205. Although the area surrounded by the dashed-dotted line is different between the transistor 200A and the wiring 205B for easy viewing in FIG. 11F, there is actually no boundary between the areas. For example, in FIG. 11F, a portion extending in the vertical direction of the stack of the semiconductor layer 230 and the conductive layer 242b can be regarded as the wiring 205B and the other portion can be regarded as part of the transistor 200A for convenience.

Part of the stack of the conductive layer 242b and the semiconductor layer 230 can be positioned to intersect with the conductive layer 245a as illustrated in FIGS. 11E and 11F because the level of the stack is different from that of the conductive layer 245a.

When part of the semiconductor layer 230 or part of the stack of the semiconductor layer 230 and the conductive layer 242 is used as a wiring or the like as described above, the design flexibility and integration degree of the semiconductor device can be increased. In addition, the semiconductor layer 230 or the stack of the semiconductor layer 230 and the conductive layer 242 can also serve as one of the wiring layers in a multilayer wiring structure, which reduces the number of production steps and results in an increase in production yield, a reduction in production cost, and the like.

The above is the description of the application example.

### Manufacturing Method Example 1

An example of a method for manufacturing the transistor of one embodiment of the present invention will be described below. Here, a method for manufacturing the transistor 200 shown in Structure example 1 above is described as an example.

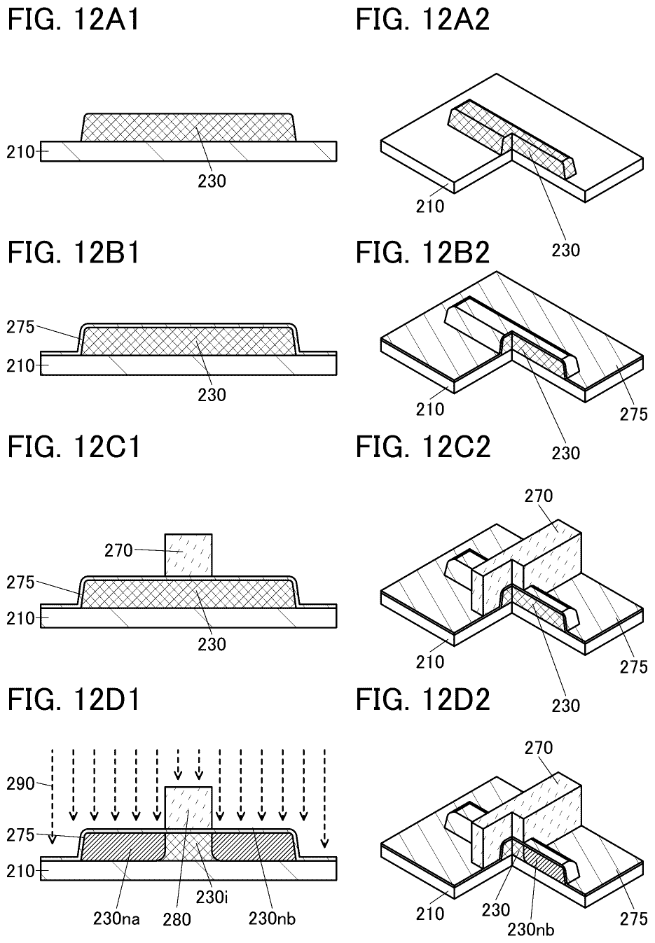

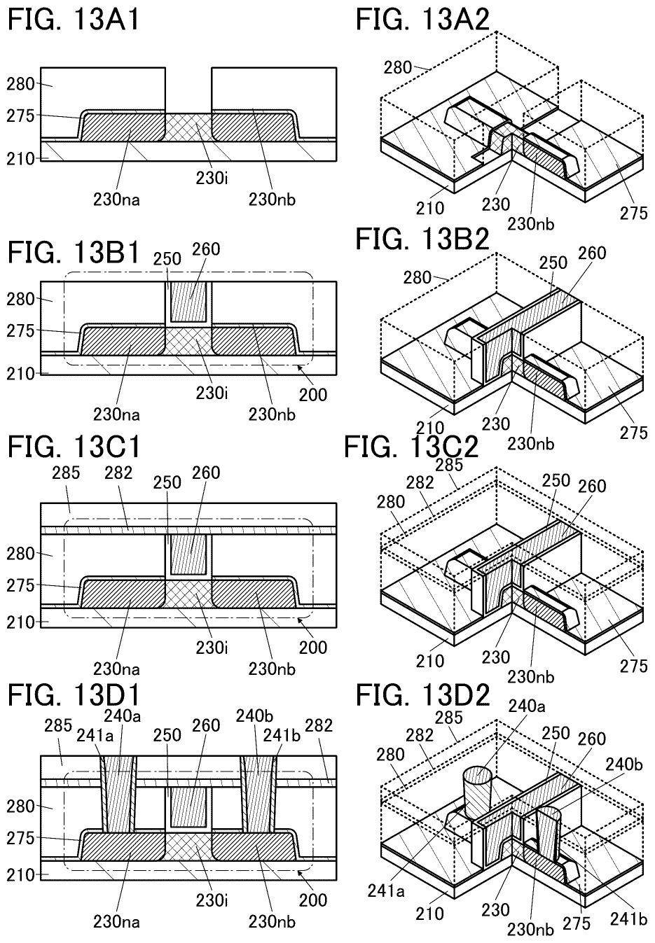

FIGS. 12A1, 12B1, 12C1, and 12D1, and FIGS. 13A1, 13B1, 13C1, and 13D1 are schematic cross-sectional views in the respective steps of the manufacturing method example shown below, and FIGS. 12A2, 12B2, 12C2, and 12D2, and FIGS. 13A2, 13B2, 13C2, and 13D2 are perspective views. Note that the cross sections of the perspective views are partly cut out. In the perspective views, some components (e.g., insulating layers) are shown to have only outlines indicated by dashed lines.

First, a semiconductor film including a single crystal region is formed over the substrate 210. For the substrate and the semiconductor film, the description of the substrate 50 and the semiconductor film 51f in Embodiment 1 can be referred to.

Heat treatment is preferably performed after the formation of the semiconductor film. For example, heat treatment can be performed at 450° C. for one hour at a flow rate ratio of a nitrogen gas to an oxygen gas of 4:1. By performing the heat treatment, the crystallinity of the semiconductor film can be improved. The heat treatment can also supply oxygen to the semiconductor film to reduce oxygen vacancies in the semiconductor film. Furthermore, hydrogen in the semiconductor film can be released by the heat treatment. Thus, the reliability of the transistor 200 can be improved.

Next, an unnecessary portion of the semiconductor film is removed by etching, so that the island-shaped semiconductor layer 230 is formed (FIGS. 12A1 and 12A2). The processing can be performed by a dry etching method or a wet etching method. A dry etching method is suitable for microfabrication. A layer functioning as a hard mask may be formed over the semiconductor film. The use of the hard mask is preferable because it improves processability and facilitates processing into a desired shape.

As illustrated in FIG. 12A1, the side surface of the semiconductor layer 230 may have a tapered shape. The taper angle of the side surface of the semiconductor layer 230 can be greater than or equal to 600 and less than 90°, for example. With such tapered side surfaces, the coverage with the insulating layer 275 and the like can be improved in a later step, so that the number of defects such as voids can be reduced.

In a lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. For example, the resist mask can be formed by exposing the resist to KrF excimer laser light, ArF excimer laser light, or extreme ultraviolet (EUV) light, for example. A liquid immersion technique may be employed in which a portion between a substrate and a projection lens is filled with a liquid (e.g., water) to perform light exposure. An electron beam or an ion beam may be used instead of the above-mentioned light. Note that a mask may be unnecessary in the case of using an electron beam or an ion beam.

To remove the resist mask which is no longer needed after the processing, dry etching treatment such as ashing using oxygen plasma (hereinafter referred to as oxygen plasma treatment in some cases) or wet etching treatment may be performed. Alternatively, wet etching treatment may be performed after dry etching treatment, or dry etching treatment may be performed after wet etching treatment.

In the case where a hard mask is used, a hard mask with a desired shape can be formed in the following manner: an insulating film or a conductive film that is the material of the hard mask is formed over the semiconductor film, a resist mask is formed thereover, and then the hard mask material is etched. The etching of the semiconductor film and the like may be performed after or without removal of the resist mask. In the latter case, the resist mask sometimes disappears during the etching. The hard mask may be removed by etching after the etching of the semiconductor film. The hard mask is not necessarily removed when the hard mask material does not affect the following process or can be utilized in the following process.

A spin on carbon (SOC) film and a spin on glass (SOG) film may be formed between an object to be processed and the resist mask. Using the SOC film and the SOG film as masks can improve the adhesion between the object to be processed and the resist mask and the durability of a mask pattern. For example, the SOC film, the SOG film, and the resist mask are formed in this order over the object to be processed and lithography can be performed.

Next, the insulating layer 275 is formed to cover the semiconductor layer 230 (FIGS. 12B1 and 12B2). The insulating layer 275 can be formed by, for example, a sputtering method, a CVD method, an MBE method, a PLD method, or an ALD method.

The insulating layer 275 is preferably formed using an insulator having a function of inhibiting passage of oxygen. For example, a silicon nitride film is preferably formed as the insulating layer 275 by a PEALD method. Alternatively, as the insulating layer 275, an aluminum oxide film may be formed by a sputtering method and a silicon nitride film may be formed thereover by a PEALD method.

Next, a mask layer 270 is formed over the insulating layer 275 (FIGS. 12C1 and 12C2). The mask layer 270 is provided to cover a portion of the semiconductor layer 230 that is to be the channel formation region (the region 230i). The mask layer 270 can be provided in a region where a groove portion is formed. The groove portion is provided in the insulating layer 280 and the like later and the insulating layer 250 and the conductive layer 260 are to be embedded in the groove portion.

The mask layer 270 can be formed using a material having high etching rate selectivity with respect to the insulating layer 275, the insulating layer 280 formed later, and the like. The mask layer 270 can also be formed using a material that functions as a mask in an element introduction step performed later. Because being a layer to be removed later, the mask layer can be formed using an optimal material selected from a variety of materials such as a metal, an alloy, an inorganic material, and an organic material. For example, an organic material such as SOC is preferably used, in which case the material can be removed by ashing later. The photosensitive organic material is also preferably used, in which case an etching step is not necessary. It is also preferable to use an inorganic material such as silicon (amorphous silicon or polycrystalline silicon), a metal, an alloy, or an inorganic insulating material because the processing accuracy can be increased and scaling down can be facilitated.

Next, with the mask layer 270 used as a mask, an element 290 is introduced into the semiconductor layer 230 through the insulating layer 275 (FIGS. 12D1 and 12D2). Thus, the region 230na and the region 230nb are formed in the semiconductor layer 230. At this time, the region 230i where the element 290 is not introduced is formed in a region of the semiconductor layer 230 that overlaps with the mask layer 270.

The element 290 can be introduced by a doping method, an ion implant method, a thermal diffusion method, or the like. Alternatively, plasma treatment, heat treatment, or the like in an atmosphere containing the element 290 can be used.

Note that in this specification and the like, the ion implant method refers to a high-purity ion doping method (also referred to as an ion injection method or an ion implantation method) using mass separation. To the contrary, the doping method refers to an ion doping method that does not use mass separation.

Examples of the element 290 include titanium, tantalum, tungsten, molybdenum, tin, silicon, germanium, zirconium, hafnium, antimony, magnesium, hydrogen, boron, and phosphorus. When such an element 290 is added to the semiconductor layer 230, the low-resistance regions 230na and 230nb can be formed.

After the introduction of the element 290, heat treatment is preferably performed. The heat treatment activates the added element to generate desired carriers in the regions 230na and 230nb. Note that in the case where the mask layer 270 has low heat resistance, the heat treatment is preferably performed after the mask layer 270 is removed.

Then, the insulating layer 280 is formed to cover the insulating layer 275 and the mask layer 270. The insulating layer 280 can be formed by, for example, a sputtering method, a CVD method, an MBE method, a PLD method, or an ALD method.

A silicon oxide film is preferably formed as the insulating layer 280 by a sputtering method. When an insulating film to be the insulating layer 280 is formed by a sputtering method in an oxygen-containing atmosphere, the insulating layer 280 containing excess oxygen can be formed. By using a sputtering method that does not need to use a molecule containing hydrogen as a film formation gas, the hydrogen concentration in the insulating layer 280 can be reduced. Note that heat treatment may be performed before the formation of the insulating film. The heat treatment may be performed under a reduced pressure, and the insulating film may be successively formed without exposure to the air. Such treatment can remove moisture and hydrogen adsorbed on the surface of the insulating layer 275 and the like. The heat treatment can be performed under the above-described heat treatment conditions.

Next, the insulating layer 280 is subjected to planarization treatment until the top surface of the mask layer 270 is exposed, and then the mask layer 270 is removed. For the planarization treatment, a chemical mechanical polishing (CMP) method, a dry etching method, or the like can be used. The mask layer 270 can be removed by dry etching or wet etching. As a result, the groove portion is formed in the insulating layer 280.

Then, a portion of the insulating layer 275 that is not covered with the insulating layer 280 (i.e., a portion positioned in the groove portion) is removed by etching to expose part of the semiconductor layer 230 (the region 230i) (FIGS. 13A1 and 13A2).

Next, the insulating layer 250 is formed to cover the groove portion formed in the insulating layers 280 and 275. Here, the insulating layer 250 is formed along the side surface of the groove portion of the insulating layer 280, and thus is preferably formed by a deposition method enabling high coverage.

The insulating layer 250 can be formed by a sputtering method, a CVD method, an MBE method, a PLD method, or an ALD method. The insulating layer 250 is preferably formed to have a small thickness and thus is preferably formed by an ALD method, which enables excellent coverage and easy control of the thickness.

When the insulating layer 250 is formed by an ALD method, ozone (O₃), oxygen (O₂), water (H₂O), or the like can be used as the oxidizer. When an oxidizer without hydrogen, such as ozone (O₃) or oxygen (O₂), is used, the amount of hydrogen diffusing into the semiconductor layer 230 can be reduced.

Microwave plasma treatment is preferably performed in an oxygen-containing atmosphere before, after, or during the formation of the insulating layer 250. This can supply oxygen to the region 230i in the semiconductor layer 230, thereby reducing oxygen vacancies.

The microwave plasma treatment refers to treatment in which high-density plasma is generated using a microwave and a film to be processed is exposed to generated ions. The frequency of the microwave is preferably higher than or equal to 300 MHz and lower than or equal to 300 GHz (typically 2.45 GHz).

The microwave plasma treatment is preferably performed under a reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., for example.

Next, a conductive film to be the conductive layer 260 is formed. The conductive film can be formed by a sputtering method, a CVD method, an MBE method, a PLD method, a plating method, or an ALD method. For example, a titanium nitride film and a tungsten film are stacked by a CVD method.

Then, the conductive films to be the insulating layer 250 and the conductive layer 260 are polished by CMP treatment until the insulating layer 280 is exposed. Thus, the insulating layer 250 and the conductive layer 260 are formed in the opening portion reaching the semiconductor layer 230 (see FIGS. 13B1 and 13B2). At this stage, the transistor 200 is formed.

Next, the insulating layer 282 is formed over the insulating layer 250, the conductive layer 260, and the insulating layer 280. The insulating layer 282 can be formed by a sputtering method, a CVD method, an MBE method, a PLD method, or an ALD method, for example. The insulating layer 282 is preferably formed by a sputtering method. Since a molecule containing hydrogen is not used as a film formation gas in a sputtering method, the concentration of hydrogen in the insulating layer 282 can be reduced.

Forming the insulating layer 282 in an oxygen-containing atmosphere by a sputtering method can add oxygen to the insulating layer 280 during the formation. Thus, excess oxygen can be contained in the insulating layer 280.

Next, the insulating layer 285 is formed over the insulating layer 282 (FIGS. 13C1 and 13C2). The insulating layer 285 can be formed by a sputtering method, a CVD method, an MBE method, a PLD method, or an ALD method. The insulating layer 285 is preferably formed by a sputtering method. Since a molecule containing hydrogen is not used as a film formation gas in a sputtering method, the concentration of hydrogen in the insulating layer 285 can be reduced.

Then, opening portions respectively reaching the region 230na and the region 230nb are formed in the insulating layers 275, 280, 282, and 285. The opening portions are formed by a lithography method. To form the opening portions, processing is preferably performed by a dry etching method. Note that the shape of the opening portions in the top view can be a circular shape, an almost circular shape such as an elliptical shape, a polygonal shape such as a quadrangular shape, or a polygonal shape such as a quadrangular shape with rounded corners, for example.

Next, an insulating film to be the insulating layers 241a and 241b is formed along the shape of the opening portions. The insulating film can be formed by a sputtering method, a CVD method, an MBE method, a PLD method, an ALD method, or the like. The insulating film to be the insulating layers 241a and 241b is formed in the opening portions having a high aspect ratio, and thus is preferably formed by an ALD method. For example, a silicon nitride film is preferably formed by a PEALD method. Silicon nitride is preferable because of its high barrier property against oxygen and hydrogen.

Next, the insulating film is etched anisotropically to form the insulating layers 241a and 241b. Providing the insulating layers 241a and 241b on the sidewall portions of the opening portions can inhibit entry of oxygen from the outside and can prevent oxidation of the conductive layers 240a and 240b formed in the next step. Furthermore, impurities such as water and hydrogen contained in the insulating layer 280 or the like can be prevented from diffusing into the conductive layers 240a and 240b. Note that part of each of the top surfaces of the regions 230na and 230nb may have a recess portion because of the anisotropic etching.

Subsequently, a conductive film to be the conductive layers 240a and 240b is formed. The conductive film desirably has a stacked-layer structure including a conductor with a function of inhibiting transmission of impurities such as water and hydrogen. For example, it is possible to employ a stacked-layer structure of tantalum nitride, titanium nitride, or the like and tungsten, molybdenum, copper, or the like. The conductive film to be the conductive layers 240a and 240b can be formed by a sputtering method, a CVD method, an MBE method, a PLD method, an ALD method, or the like.

Then, the conductive film to be the conductive layers 240a and 240b is partly removed by CMP treatment, thereby exposing the top surface of the insulating layer 285 (FIGS. 13D1 and 13D2). As a result, the conductive layers 240a and 240b can be formed. Note that the CMP treatment may remove part of the top surface of the insulating layer 285.

Heat treatment may be further performed after the formation of the conductive layers 240a and 240b. This heat treatment can be performed under the conditions similar to those for the above heat treatment. By the heat treatment, the amount of oxygen supplied to the oxide semiconductor layer 230 can be adjusted. Thus, the reliability and electrical characteristics of the transistor 200 can be improved.

Through the above process, the semiconductor device including the transistor 200 shown in Structure example 1 can be manufactured.

### Manufacturing Method Example 2

An example of a method for manufacturing the transistor 200A shown in Structure example 2 above will be described below. Note that for portions similar to those in Manufacturing method example 1 above, the description in Manufacturing method example 1 is referred to and is not repeated in some cases.

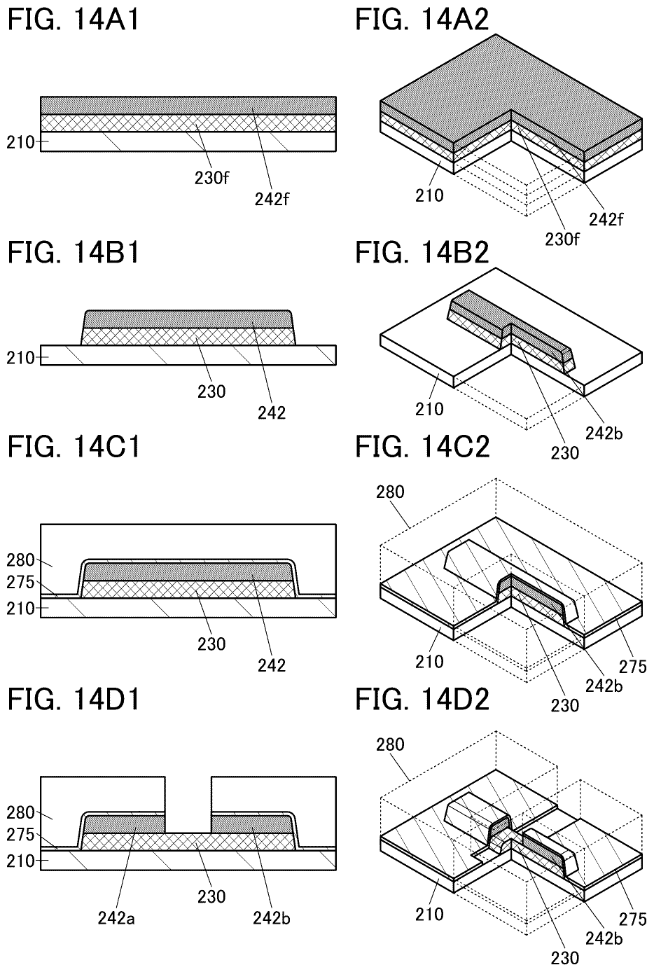

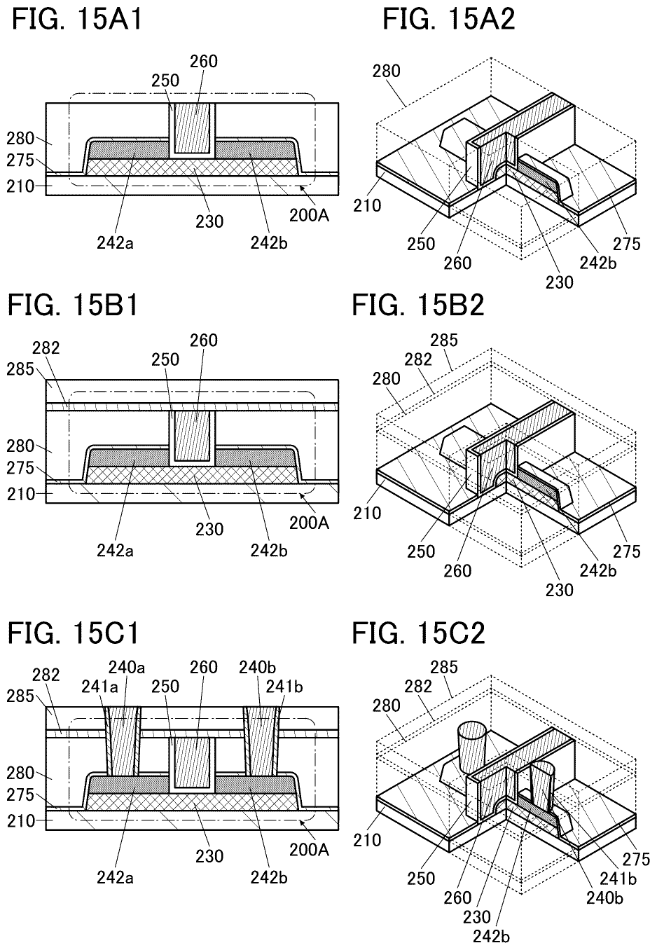

FIGS. 14A1, 14B1, 14C1, and 14D1, and FIGS. 15A1, 15B1, and 15C1 are schematic cross-sectional views in the respective steps of the manufacturing method example shown below, and FIGS. 14A2, 14B2, 14C2, and 14D2, and FIGS. 15A2, 15B2, and 15C2 are perspective views.

First, a semiconductor film 230f is formed over the substrate 210, and a conductive film 242f is formed over the semiconductor film 230f (FIGS. 14A1 and 14A2). For the semiconductor film 230f, the description of the semiconductor film 51f in Embodiment 1 can be referred to.

The conductive film 242f is a film to be the conductive layers 242a and 242b. The conductive film 242f can be formed by a sputtering method, a CVD method, an MBE method, a PLD method, or an ALD method.

Next, the semiconductor film 230f and the conductive film 242f are processed into island shapes by a lithography method to form the semiconductor layer 230 and the conductive layer 242 (FIGS. 14B1 and 14B2).

In the processing, a layer functioning as a hard mask may be formed over the conductive film 242f The use of the hard mask is preferable because it improves processability and facilitates processing into a desired shape.

Here, the semiconductor layer 230 and the conductive layer 242 are preferably processed into island shapes at a time. In that case, a side end portion of the conductive layer 242 is preferably aligned or substantially aligned with a side end portion of the semiconductor layer 230. With such a structure, the number of steps for the semiconductor device of one embodiment of the present invention can be reduced. Thus, a method for manufacturing a semiconductor device with high productivity can be provided.

Next, the insulating layer 275 is formed to cover the semiconductor layer 230 and the conductive layer 242, and the insulating layer 280 is formed over the insulating layer 275 (FIGS. 14C1 and 14C2).

Next, the conductive layer 242, the insulating layer 275, and the insulating layer 280 are partly etched to form a groove portion reaching the semiconductor layer 230 and the substrate 210 (FIGS. 14D1 and 14D2). Here, the conductive layer 242 is divided into the conductive layer 242a and the conductive layer 242b.

Next, the insulating layer 250 and the conductive layer 260 are formed to cover the groove portion provided in the insulating layer 280 and the like, and planarization treatment is performed so that the top surface of the insulating layer 280 is exposed, whereby the insulating layer 250 and the conductive layer 260 positioned in the groove portion are formed (FIGS. 15A1 and 15A2). Through the above-described steps, the transistor 200A is formed.

Then, the insulating layer 282 and the insulating layer 285 are formed (FIGS. 15B1 and 15B2).

After that, a pair of opening portions respectively reaching the conductive layer 242a and the conductive layer 242b are formed in the insulating layers 285, 282, 280, and 275, and the insulating layer 241a and the insulating layer 241b are formed in the opening portions. Then, the conductive layer 240a in contact with the conductive layer 242a and the conductive layer 240b in contact with the conductive layer 242b are formed in the respective opening portions (FIGS. 15C1 and 15C2).

Through the above process, the semiconductor device including the transistor 200A shown in Structure example 2 can be manufactured.

At least part of this embodiment can be implemented as appropriate in combination with any of the other embodiments described in this specification.

### Embodiment 3

Described in this embodiment is an indium oxide film that can be used for the semiconductor layer of the transistor of one embodiment of the present invention.

Note that in this specification and the like, indium oxide including at least a crystal part or a crystal region in a film is referred to as crystal indium oxide (crystal IO) or crystalline indium oxide (crystalline IO). Examples of crystal IO or crystalline IO include single crystal indium oxide, polycrystal indium oxide, and microcrystal indium oxide.

Indium oxide is a semiconductor material having physical properties completely different from those of an oxide semiconductor such as In—Ga—Zn oxide (hereinafter, also referred to as IGZO) or zinc oxide.

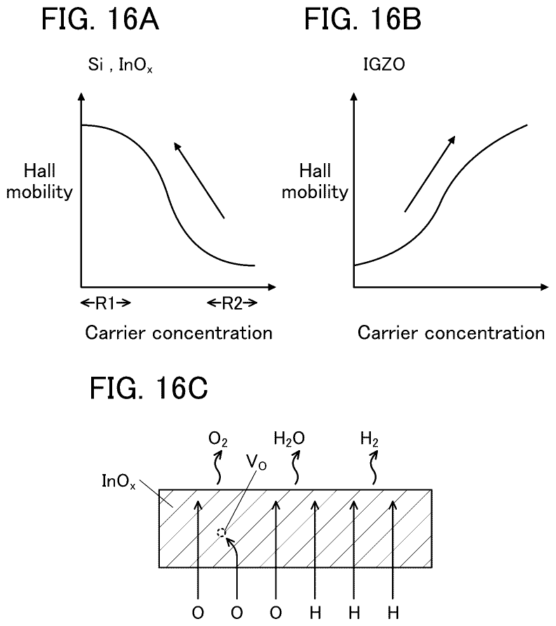

The dependence of the Hall mobility on the carrier concentration of indium oxide, silicon, and IGZO will be described. FIG. 16A is a schematic view showing the dependence of the Hall mobility on the carrier concentration of silicon (Si) and indium oxide (InOₓ), and FIG. 16B is a schematic view showing the dependence of the Hall mobility on the carrier concentration of IGZO.

As indicated by an arrow in FIG. 16B, IGZO has a tendency in which the Hall mobility is higher as the carrier concentration is higher. By contrast, as indicated by an arrow in FIG. 16A, indium oxide has a tendency in which the Hall mobility is higher as the carrier concentration is lower (see Non-Patent Document 3). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 16A are based on the assumption of single crystal indium oxide; thus, the characteristics of non-single-crystal (e.g., polycrystal) indium oxide are sometimes different from those in FIG. 16A.

In FIG. 16A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties. As a method for supplying the element that increases the carrier concentration, a method in which a film containing the element is formed to diffuse the element, an ion implantation method, an ion doping method, a plasma immersion ion implantation method, or plasma treatment can be employed. In this specification and the like, whether or not mass separation is performed is not limited, unless otherwise specified. In this specification and the like, a method by which mass-separated ions are supplied is referred to as an ion implantation method, and a method by which non-mass-separated ions are supplied is referred to as an ion doping method, for example.

In this manner, the region with a low carrier concentration and the region with a high carrier concentration of indium oxide are used as a channel formation region and source and drain regions, respectively, of a transistor. In other words, indium oxide is an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 16A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following features (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

The expression “a semiconductor is of an i-type” can be replaced with the expression “the Fermi level (Ef) is equal to the intrinsic Fermi level (Ei) (Ef=Ei)”. As shown in FIG. 16B, the Hall mobility is lower as the carrier concentration is lower in IGZO. Accordingly, in the case where Ef eventually becomes equal to Ei, carriers disappear (i.e., the physical properties of IGZO become similar to those of an insulator) and a transistor containing IGZO cannot operate. By contrast, the Hall mobility is higher as the carrier concentration is lower in indium oxide as shown in FIG. 16A. In the case where Ef eventually becomes equal to Ei, the Hall mobility is the highest. That is, a transistor containing indium oxide can have high field-effect mobility when Ef is equal to Ei. Note that a transistor containing indium oxide has a low carrier concentration and thus tends to be normally off. Hence, a transistor containing indium oxide can have both normally-off characteristics and high field-effect mobility.

Normally off means a state where no current flows through a transistor when a potential is not applied to its gate or its gate-source voltage is 0 V. The normally-off characteristics can be evaluated using the threshold voltage (Vth) or shift value (Vsh) of a transistor. Note that Vth is calculated by a constant current method unless otherwise specified. Specifically, Vth is gate voltage (Vg) at which a value of drain current (Id)×channel length (L)÷channel width (W) in the Id−Vg characteristics of a transistor is 1 nA (1×1⁻⁹ A). Vsh is gate voltage (Vg) at a point of intersection of a straight line of Id=1 pA (1×10⁻¹² A) and a tangent line of drain current (Id) on a logarithmic scale that has the highest gradient in the Id-Vg characteristics of the transistor, or gate voltage (Vg) at a point of intersection of a straight line of Id=1 pA and a straight line extrapolated from two points where the slope of Id on a logarithmic scale has the highest gradient in the Id−Vg characteristics of the transistor. For example, when at least one of Vth and Vsh is 0 or a positive value, the transistor can be regarded as being normally off.

In order that a semiconductor can be of an i-type, i.e., Ef can be equal to Ei, in a transistor containing indium oxide, the structure of a film in contact with an indium oxide film is important. For example, a transistor containing indium oxide can have a film structure in which a silicon oxide film, which is in contact with an indium oxide film, a hafnium oxide film, and a silicon nitride film are stacked. Such a film structure can achieve Ef=Ei, enabling a semiconductor device to have high reliability.

In the above film structure, a film containing oxygen, such as a silicon oxynitride film, a silicon nitride oxide film, an aluminum oxide film, or a gallium oxide film, can be used instead of the silicon oxide film. Also in the above film structure, a silicon nitride oxide film, a silicon oxynitride film, or the like can be used instead of the silicon nitride film. The hafnium oxide film that is closer to the indium oxide film than the silicon nitride film is functions as a hydrogen gettering site.

The above film structure can be regarded as a structure in which a film that is capable of supplying oxygen to the indium oxide film (e.g., the silicon oxide film), a film that is capable of gettering hydrogen (e.g., the hafnium oxide film), and a film that is capable of inhibiting entry of oxygen and hydrogen (e.g., the silicon nitride film) are stacked in this order from the indium oxide film side. With this structure, oxygen vacancies in the indium oxide film are filled with oxygen in the silicon oxide film. Moreover, hydrogen in the indium oxide film is captured in the hafnium oxide film by heat treatment or the like. Providing the silicon nitride film inhibits entry of oxygen and hydrogen from the outside. That is, the above film structure enables the indium oxide film to be closer to an i-type film. Thus, a transistor including the indium oxide film has high field-effect mobility and high reliability.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. Note that in the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

The crystallinity of indium oxide can be analyzed with an X-ray diffraction (XRD) pattern, a transmission electron microscope (TEM) image, or an electron diffraction (ED) pattern, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film in the channel formation region may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

An indium oxide film in this specification and the like has high film density. The theoretical film density of the indium oxide film is 7.18 g/cm³. The film density of the indium oxide film in this specification and the like ranges from 6.70 g/cm³ to 7.18 g/cm³, preferably from 6.90 g/cm³ to 7.18 g/cm³, further preferably from 7.00 g/cm³ to 7.18 g/cm³.

The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a TE image is pale (bright) when the film density is low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), still further preferably higher than or equal to 200 cm²/(V·s), yet still further preferably higher than or equal to 250 cm²/(V·s).

One feature of an indium oxide film is to have a higher property of transmitting (diffusing) oxygen than an IGZO film. As shown in FIG. 16C, oxygen (O) diffusing in an indium oxide film (denoted as InOₓ) is transmitted through the indium oxide film and released as an oxygen molecule (O₂). When reacting with hydrogen contained in the film, oxygen is released as a water molecule (H₂O) in some cases. In the case where the film includes oxygen vacancies (Vₒ), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 16C, hydrogen diffuses in the indium oxide film. Hydrogen diffusing into the indium oxide film from the outside is transmitted through the indium oxide film and is released as a hydrogen molecule (H₂). When reacting with oxygen contained in the film, hydrogen is released as a water molecule. Note that oxygen and hydrogen described above diffuse in the indium oxide film by heat treatment. The temperature of the heat treatment is higher than or equal to 200° C. and lower than or equal to 700° C., preferably higher than or equal to 350° C. and lower than or equal to 650° C., further preferably higher than or equal to 400° C. and lower than or equal to 500° C.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor containing indium oxide with a small effective mass of electrons can have high on-state current or high field-effect mobility.

Table 1 shows the effective mass in each of single crystal indium oxide (here, In₂O₃) and single crystal silicon (Si). As shown in Table 1, indium oxide has features of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 1, a transistor containing indium oxide can have higher field-effect mobility and lower off-state current than a Si transistor.

TABLE 1
Effective mass in In₂O₃

| Electron | | | |
|---|---|---|---|
| [100] direction | [110] direction | [111] direction | Hole |
| 0.17 | 0.18 | 0.19 | 3.56 |

Effective mass in Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single crystal substrate) may be used.

One of methods for evaluating a lattice mismatching level is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, still further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to a YSZ crystal having the cubic crystal structure is within the range of −2% to 2%, which enables epitaxial growth of a single crystal film of indium oxide on the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single crystal film of indium oxide can be formed not only over a YSZ substrate but also over an insulating film. By contrast, a single crystal film of silicon is not easily formed over an insulating film. Note that a silicon crystal has a diamond structure. Thus, although indium oxide and silicon exhibit similar characteristics as single crystals, they differ in whether a single crystal can be formed over an insulating film.

At least part of this embodiment can be implemented as appropriate in combination with any of the other embodiments described in this specification.

### Embodiment 4

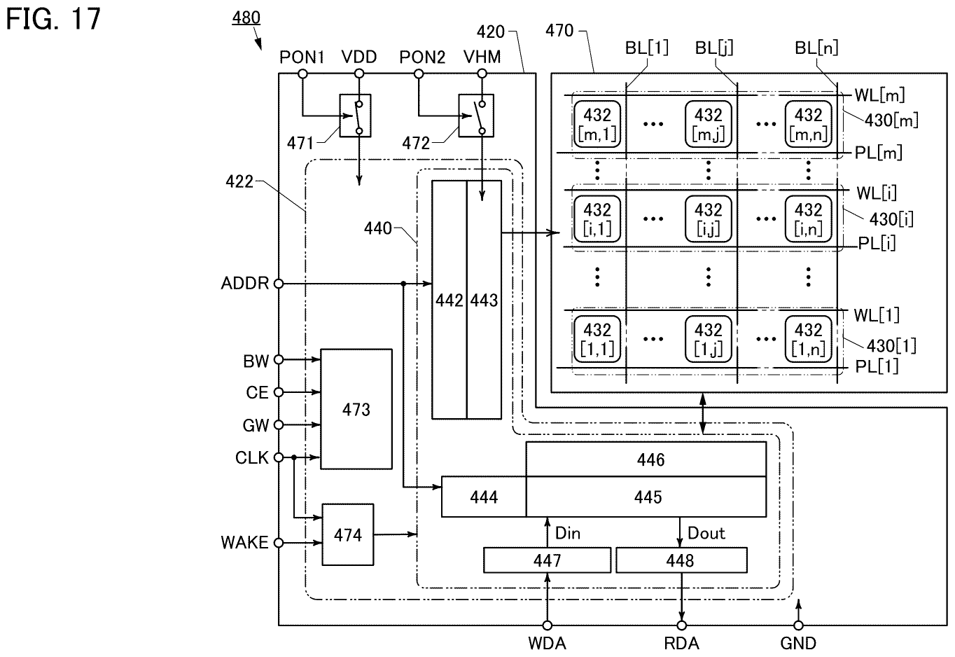

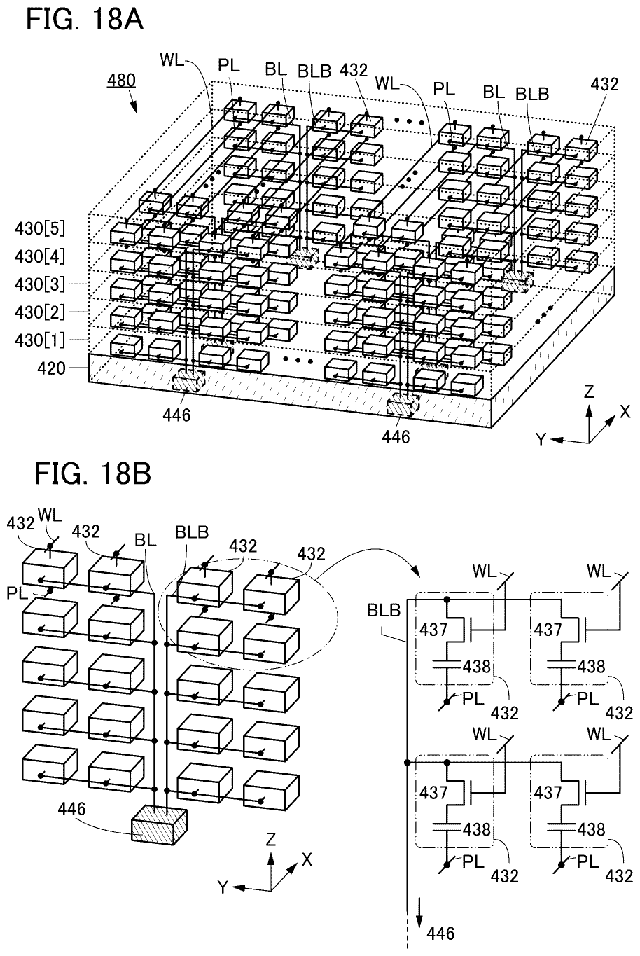

In this embodiment, a memory device of one embodiment of the present invention will be described with reference to FIG. 17, FIGS. 18A and 18B, FIGS. 19A to 19D, and FIG. 20.

Described in this embodiment is a structure example of a memory device in which a layer including memory cells is stacked over a layer provided with a driver circuit including a sense amplifier.

The transistor (denoted as an OS transistor) in which a channel is formed in an oxide semiconductor including a single crystal region, which is shown in Embodiment 2, can be used as a transistor included in a memory cell shown below.

### Structure Example of Memory Device

FIG. 17 is a block diagram illustrating a structure example of a memory device 480 according to one embodiment of the present invention. The memory device 480 illustrated in FIG. 17 includes a layer 420 and a layer 470 stacked thereover.

The layer 420 is a layer including Si transistors. The layer 470 is provided with element layers 430[1] to 430[m] (m is an integer greater than or equal to 2) as stacked layers. The element layers 430 include OS transistors. The layer 470 can be stacked over the layer 420.

Note that in this specification and the like, in the description of matters common to components that are distinguished from each other using alphabets or numbers added to reference numerals (such as the element layer 430[1] and a memory cell 432[m, n]), reference numerals without alphabets or numbers (such as the element layer 430 and the memory cell 432) are sometimes used.

The element layer 430 includes the memory cells 432 each formed of an OS transistor and a capacitor. FIG. 17 illustrates an example in which the element layers 430[1] to 430[m] include a plurality of memory cells 432 arranged in a matrix of m rows and n columns (n is an integer greater than or equal to 2).

A memory cell 432[1,1] is a memory cell in the first row and the first column, and the memory cell 432[m,n] is a memory cell in the m-th row and the n-th column. A given row is denoted as an i-th row, a j-th column, or the like in some cases (i is an integer greater than or equal to 1 and less than or equal to m, and j is an integer greater than or equal to 1 and less than or equal to n).

FIG. 17 illustrates m wirings WL extending in a row direction, m wirings PL extending in the row direction, and n wirings BL extending in a column direction. The plurality of memory cells 432 provided in the i-th row are connected to a wiring WL[i] in the i-th row and a wiring PL[i] in the i-th row.

The wiring BL functions as a bit line for writing and reading data. The wiring WL functions as a word line for controlling on or off (a conduction state or a non-conduction state) of an access transistor serving as a switch. The wiring PL has a function of a constant potential line connected to a capacitor. Note that a wiring for transmitting a back gate potential can be additionally provided.

The memory cells 432 are connected to a sense amplifier 446 through the wirings BL. The wirings BL can be provided with wirings arranged horizontally and perpendicularly to the surface of the substrate. This can shorten the length of the wiring between the element layer 430 and the sense amplifier 446. Thus, the resistance and parasitic capacitance of the wirings BL can be significantly reduced, so that the power consumption and signal delay of the memory device 480 can be reduced. Moreover, operation is possible even when the capacitance of the capacitors included in the memory cells 432 is reduced, achieving downsizing of the memory device 480.

The layer 420 includes a PSW 471 (power switch), a PSW 472, and a peripheral circuit 422. The peripheral circuit 422 includes a driver circuit 440, a control circuit 473, and a voltage generation circuit 474. Note that each circuit included in the layer 420 includes a Si transistor.

In the memory device 480, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 473.

The control circuit 473 is a logic circuit having a function of controlling the entire operation of the memory device 480. For example, the control circuit performs logical operation on the signals CE, GW, and BW to determine an operation mode (e.g., write operation or read operation) of the memory device 480. Alternatively, the control circuit 473 generates a control signal for the driver circuit 440 so that the operation mode is executed.

The voltage generation circuit 474 has a function of generating negative voltage. The signal WAKE has a function of controlling the input of the signal CLK to the voltage generation circuit 474. For example, when an H-level signal is supplied as the signal WAKE, the signal CLK is input to the voltage generation circuit 474, and the voltage generation circuit 474 generates a negative voltage.

The driver circuit 440 is a circuit for writing and reading data to/from the memory cells 432. The driver circuit 440 includes the above-described sense amplifier 446 in addition to a row decoder 442, a column decoder 444, a row driver 443, a column driver 445, an input circuit 447, and an output circuit 448.

The row decoder 442 and the column decoder 444 have a function of decoding the signal ADDR. The row decoder 442 is a circuit for specifying a row to be accessed, and the column decoder 444 is a circuit for specifying a column to be accessed. The row driver 443 has a function of selecting the wiring WL specified by the row decoder 442. The column driver 445 has a function of writing data to the memory cells 432, a function of reading data from the memory cells 432, a function of retaining the read data, and the like.

The input circuit 447 has a function of retaining the signal WDA. Data retained by the input circuit 447 is output to the column driver 445. Data output from the input circuit 447 is data (Din) to be written to the memory cells 432. Data (Dout) read from the memory cells 432 by the column driver 445 is output to the output circuit 448. The output circuit 448 has a function of retaining Dout. In addition, the output circuit 448 has a function of outputting Dout to the outside of the memory device 480. Data output from the output circuit 448 is the signal RDA.

The PSW 471 has a function of controlling the supply of VDD to the peripheral circuit 422. The PSW 472 has a function of controlling the supply of VHM to the row driver 443. Here, in the memory device 480, a high power supply potential is VDD and a low power supply potential is GND (a ground potential). In addition, VHM is a high power supply potential used to set the word line at a high level and is higher than VDD. The on/off of the PSW 471 is controlled by the signal PON1, and the on/off of the PSW 472 is controlled by the signal PON2. The number of power domains to which VDD is supplied is one in the peripheral circuit 422 in FIG. 17 but can be two or more. In that case, a power switch is provided for each power domain.

The element layers 430[1] to 430[m] can be stacked over the layer 420. FIG. 18A illustrates a perspective view of the memory device 480 in which five (m=5) element layers 430[1] to 430[5] are stacked over the layer 420.

FIG. 18A also illustrates the wiring WL and the wiring PL provided to extend in the X direction and the wiring BL and a wiring BLB provided to extend in the Y direction and the Z direction (the direction perpendicular to the surface of the substrate where the driver circuit is provided). The wiring BLB is an inverted bit line. Note that for easy viewing of the drawing, some of the wirings WL and the wirings PL included in the element layers 430 are not illustrated.

FIG. 18B illustrates a schematic view of the sense amplifier 446 and the memory cells 432, which are connected through the wiring BL and the wiring BLB. Note that a structure where a plurality of memory cells are connected to one bit line is also referred to as “memory string”.

FIG. 18B illustrates an example of a circuit structure of the memory cells 432 connected to the wiring BLB. Each of the memory cells 432 includes a transistor 437 and a capacitor 438.

One of a source and a drain of the transistor 437 is connected to the wiring BLB, the other is connected to one electrode of the capacitor 438, and a gate of the transistor 437 is connected to the wiring WL. The other electrode of the capacitor 438 is connected to the wiring PL.

The wiring PL is a wiring for supplying a constant potential to the capacitor 438. When a plurality of wirings PL are connected to each other and used as one wiring, the number of wirings can be reduced.

In one embodiment of the present invention, memory cells including OS transistors are stacked and a bit line is provided to extend in the direction perpendicular to the surface of the substrate. Accordingly, the length of a wiring between element layers can be shortened and the density of elements per unit area can be increased. Thus, the memory device can have excellent memory capacity and be excellent in reducing power consumption.

### Structure Examples of Memory Cell 432 and Sense Amplifier 446

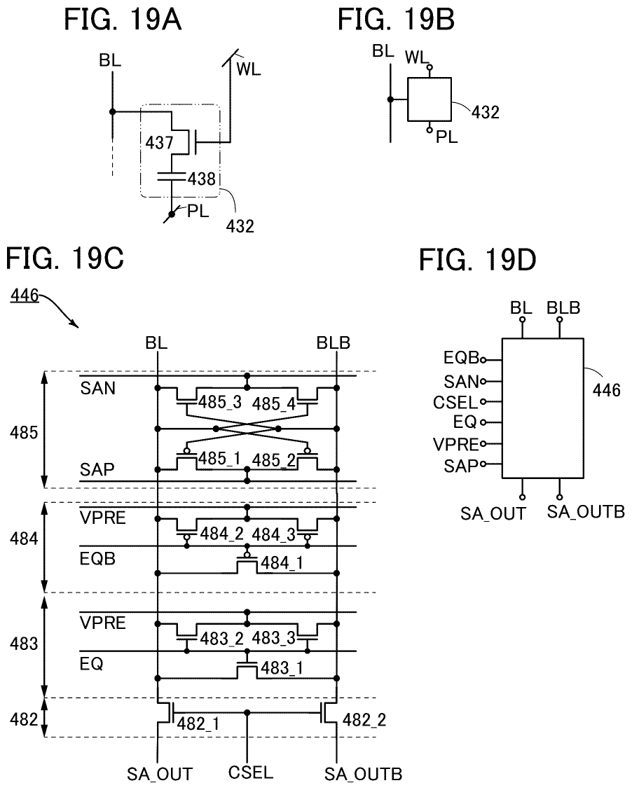

FIGS. 19A and 19B illustrate a circuit diagram corresponding to the above-described memory cell 432 and a circuit block diagram corresponding to the circuit diagram. Note that the same applies to the case where the wiring BL is replaced with the wiring BLB.

FIGS. 19C and 19D illustrate a circuit diagram corresponding to the above-described sense amplifier 446 and a circuit block diagram corresponding to the circuit diagram. The sense amplifier 446 includes a switch circuit 482, a precharge circuit 483, a precharge circuit 484, and an amplifier circuit 485. In addition, a wiring SA_OUT and a wiring SA_OUTB that output a signal are illustrated.

The switch circuit 482 includes n-channel transistors 482_1 and 482_2. The transistors 482_1 and 482_2 switch a conduction state between a wiring pair of the wiring SA_OUT and the wiring SA_OUTB and a wiring pair of the wiring BL and the wiring BLB in response to a signal CSEL.

The precharge circuit 483 includes n-channel transistors 483_1 to 483_3. The precharge circuit 483 is a circuit for precharging the wiring BL and the wiring BLB with an intermediate potential VPRE corresponding to a potential VDD/2 in response to a signal EQ.

The precharge circuit 484 includes p-channel transistors 484_1 to 484_3. The precharge circuit 484 is a circuit for precharging the wiring BL and the wiring BLB with the intermediate potential VPRE corresponding to the potential VDD/2 in response to a signal EQB.

The amplifier circuit 485 includes p-channel transistors 485_1 and 485_2 connected to a wiring SAP and n-channel transistors 485_3 and 485_4 connected to a wiring SAN. The wiring SAP or the wiring SAN is a wiring having a function of supplying VDD or VSS. The transistors 485_1 to 485_4 are transistors that form an inverter loop.

FIG. 19D illustrates a circuit block diagram corresponding to the sense amplifier 446.

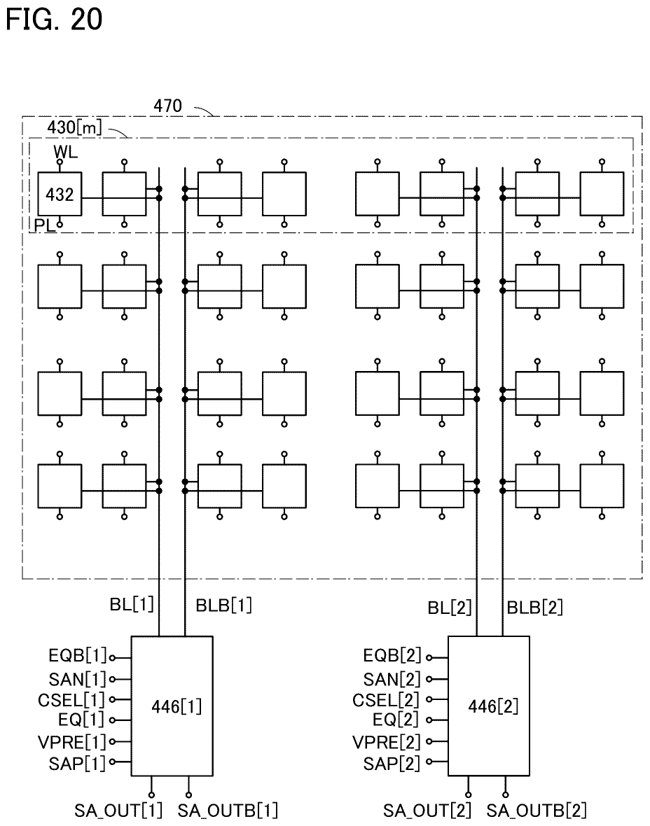

FIG. 20 illustrates a circuit block diagram of the memory device 480 in FIG. 17. As illustrated in FIG. 20, the layer 470 includes a plurality of memory cells 432. The memory cells 432 are connected to the wiring BL or the wiring BLB. The memory cells 432 connected to the wiring BL are memory cells to/from which data is written or read.

The wirings BL and BLB are connected to the sense amplifier 446. The sense amplifier 446 can perform data reading in accordance with the various signals described with reference to FIG. 19C.

At least part of this embodiment can be implemented as appropriate in combination with any of the other embodiments described in this specification.

### Embodiment 5

Described in this embodiment are structure examples of a display device that can employ the transistor of one embodiment of the present invention.

Since the transistor of one embodiment of the present invention can be extremely minute, a display device that employs the transistor of one embodiment of the present invention can be an extremely high-resolution display device. For example, a display device of one embodiment of the present invention can be used for display portions of information terminal devices (wearable devices) such as wristwatch-type and bracelet-type information terminal devices and display portions of devices that can be worn on a head, such as a device for VR like a head-mounted display, or a glasses-type device for AR.

In the display device of one embodiment of the present invention, a driver circuit and a pixel circuit can be provided to overlap with each other. In that case, the transistor in which a channel is formed in an oxide semiconductor including a single crystal region, which is shown in Embodiment 2, can be used as a transistor included in a pixel.

### [Display Module]

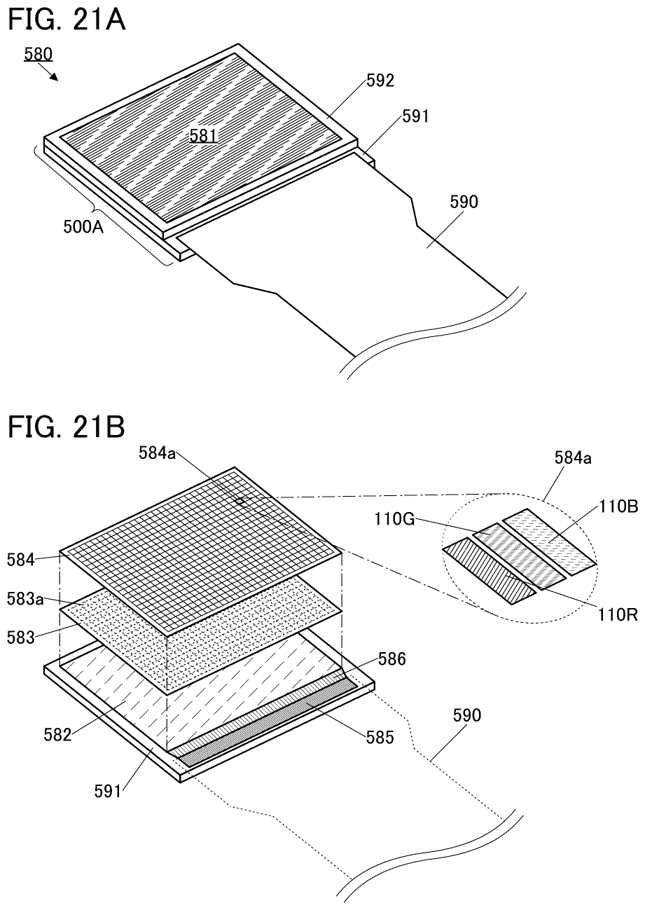

FIG. 21A is a perspective view of a display module 580. The display module 580 includes a display device 500A and an FPC 590. The display module 580 includes a substrate 591 and a substrate 592. The display module 580 includes a display portion 581. The display portion 581 is a region where an image is displayed.

FIG. 21B is a perspective view schematically illustrating a structure on the substrate 591 side. Over the substrate 591, a circuit portion 582, a pixel circuit portion 583 over the circuit portion 582, and a pixel portion 584 over the pixel circuit portion 583 are stacked. In addition, a terminal portion 585 to be connected to the FPC 590 is provided in a portion over the substrate 591 that does not overlap with the pixel portion 584. The terminal portion 585 and the circuit portion 582 are connected to each other through a wiring portion 586 formed of a plurality of wirings.

The pixel portion 584 includes a plurality of pixels 584a arranged periodically. An enlarged view of one pixel 584a is illustrated on the right side in FIG. 21B. The pixel 584a includes a light-emitting element 110R that emits red light, a light-emitting element 110G that emits green light, and a light-emitting element 110B that emits blue light.

The pixel circuit portion 583 includes a plurality of pixel circuits 583a arranged periodically. One pixel circuit 583a is a circuit for controlling light emission of three light-emitting devices included in one pixel 584a. One pixel circuit 583a may be provided with three circuits for controlling light emission of one light-emitting device. For example, the pixel circuit 583a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 582 includes a circuit for driving the pixel circuits 583a in the pixel circuit portion 583. For example, the circuit portion 582 preferably includes one or both ofa gate line driver circuit and a source line driver circuit. The circuit portion 582 may further include at least one of an arithmetic circuit, a memory circuit, a power supply circuit, and the like. In addition, a transistor provided in the circuit portion 582 may constitute part of the pixel circuit 583a. That is, the pixel circuit 583a may be constituted by a transistor included in the pixel circuit portion 583 and a transistor included in the circuit portion 582.

The FPC 590 functions as a wiring for supplying a video signal, a power supply potential, and the like to the circuit portion 582 from the outside. In addition, an IC may be mounted on the FPC 590.

The display module 580 can have a structure in which one or both of the pixel circuit portion 583 and the circuit portion 582 are stacked below the pixel portion 584; thus, the aperture ratio (effective display area ratio) of the display portion 581 can be significantly high. For example, the aperture ratio of the display portion 581 can be greater than or equal to 40% and less than 100%, preferably greater than or equal to 50% and less than or equal to 95%, further preferably greater than or equal to 60% and less than or equal to 95%. Furthermore, the pixels 584a can be arranged extremely densely and thus the display portion 581 can have extremely high resolution. For example, the pixels 584a are preferably arranged in the display portion 581 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 580 has extremely high resolution, and thus can be suitably used for a device for VR such as a head-mounted display, or a glasses-type device for AR. For example, even with a structure in which the display portion of the display module 580 is viewed through a lens, pixels of the extremely-high-resolution display portion 581 included in the display module 580 are not recognized even when the display portion is enlarged by the lens, so that display providing a high sense of immersion can be performed. Without being limited thereto, the display module 580 can be suitably used for an electronic apparatus having a comparatively small display portion. For example, the display module 580 can be suitably used in a display portion of a wearable electronic apparatus, such as a wristwatch.

### [Display Device 500A]

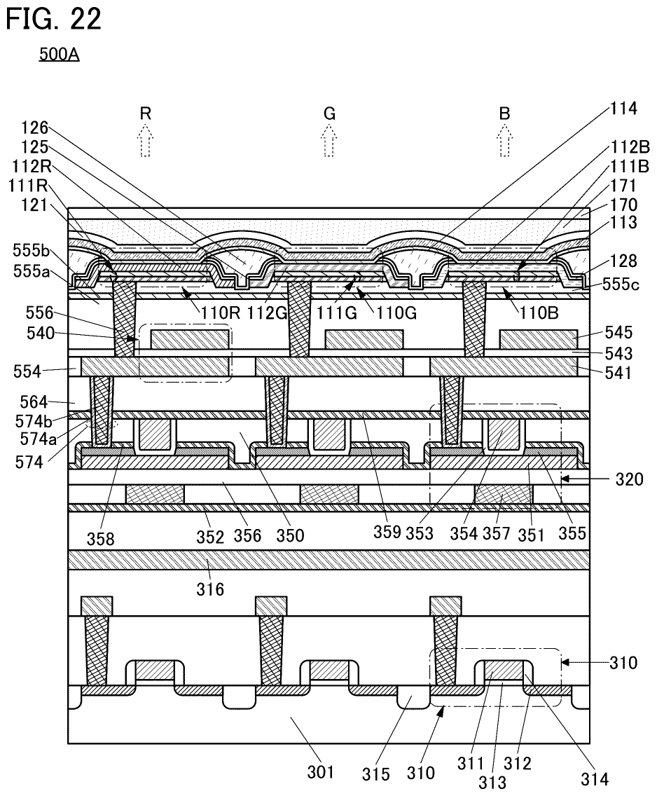

The display device 500A illustrated in FIG. 22 includes a substrate 301, the light-emitting element 110R, the light-emitting element 110G, the light-emitting element 110B, a capacitor 540, a transistor 310, and a transistor 320.

The transistor 310 is a transistor in which a channel is formed in a single crystal substrate. As the transistor 320, the transistor shown in Embodiment 2, in which a channel is formed in a single crystal oxide semiconductor, can be used.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The 5 conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and serves as a source and a drain. The insulating layer 314 is provided to cover side surfaces of the conductive layer 311.

An element isolation layer 315 is provided between two adjacent transistors 310 to be embedded in the substrate 301.

The transistor 320 includes a semiconductor layer 351, an insulating layer 353, a conductive layer 354, a pair of conductive layers 355, an insulating layer 356, and a conductive layer 357.

An insulating layer 352 is provided over a layer where the transistor 310 is provided with a wiring layer 316 and an interlayer insulating layer therebetween. The insulating layer 352 functions as a barrier layer that prevents diffusion of impurities from the substrate 301 side into the transistor 320 and release of oxygen from the semiconductor layer 351 to the insulating layer 352 side. As the insulating layer 352, for example, a film in which hydrogen or oxygen is less likely to diffuse than in a silicon oxide film, such as an aluminum oxide film, a hafnium oxide film, or a silicon nitride film, can be used.

The conductive layer 357 is provided over the insulating layer 352, and the insulating layer 356 is provided to cover the conductive layer 357. The conductive layer 357 functions as a second gate electrode of the transistor 320, and part of the insulating layer 356 functions as a second gate insulating layer. An oxide insulating film such as a silicon oxide film is preferably used for at least a portion of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as oxide semiconductor) film exhibiting semiconductor characteristics. The pair of conductive layers 355 are provided on and in contact with the semiconductor layer 351, and functions as a source electrode and a drain electrode.

An insulating layer 358 and an insulating layer 350 are provided to cover top surfaces and side surfaces of the pair of conductive layers 355, side surfaces of the semiconductor layer 351, and the like. The insulating layer 358 functions as a barrier layer that prevents diffusion of impurities such as water and hydrogen into the semiconductor layer 351 and release of oxygen from the semiconductor layer 351. As the insulating layer 358, an insulating film similar to the insulating layer 352 can be used.

An opening portion reaching the semiconductor layer 351 is provided in the insulating layers 358 and 350. The conductive layer 354 and the insulating layer 353 that is in contact with the top surface of the semiconductor layer 351 are embedded in the opening portion. The conductive layer 354 functions as a first gate electrode, and the insulating layer 353 functions as a first gate insulating layer.

The top surface of the conductive layer 354, the top surface of the insulating layer 353, and the top surface of the insulating layer 350 are subjected to planarization treatment so that they are level with or substantially level with each other, and an insulating layer 359 is provided to cover these layers. The insulating layer 359 functions as a barrier layer that prevents diffusion of impurities such as water and hydrogen into the transistor 320. For the insulating layer 359, an insulating film similar to the insulating layer 352 can be used.

A structure in which the semiconductor layer where a channel is formed is sandwiched between two gates is employed for the transistor 320. The two gates may be connected to each other and supplied with the same signal to drive the transistor. Alternatively, a potential for controlling the threshold voltage may be applied to one of the two gates and a potential for driving may be applied to the other of the two gates to control the threshold voltage of the transistor.

An insulating layer 564 is provided over the insulating layer 359. The insulating layer 564 functions as an interlayer insulating layer.

A plug 574 connected to one of the conductive layers 355 is provided to be embedded in the insulating layers 564, 359, 350, and 358. Here, the plug 574 preferably includes a conductive layer 574a that covers side surfaces of opening portions in the insulating layer 564 and the like and part of the top surface of the conductive layer 355, and a conductive layer 574b in contact with the top surface of the conductive layer 574a. In that case, a conductive material in which oxygen is less likely to diffuse is preferably used for the conductive layer 574a.

The capacitor 540 is provided over the insulating layer 564. The capacitor 540 includes a conductive layer 541, a conductive layer 545, and an insulating layer 543 positioned therebetween. The conductive layer 541 functions as one electrode of the capacitor 540, the conductive layer 545 functions as the other electrode of the capacitor 540, and the insulating layer 543 functions as a dielectric of the capacitor 540.

The conductive layer 541 is embedded in an insulating layer 554 provided over the insulating layer 564. The conductive layer 541 is electrically connected to the conductive layer 355 of the transistor 320 through the plug 574. The insulating layer 543 is provided to cover the conductive layer 541. The conductive layer 545 is provided in a region overlapping the conductive layer 541 with the insulating layer 543 therebetween.

An insulating layer 555a is provided to cover the capacitor 540, an insulating layer 555b is provided over the insulating layer 555a, and an insulating layer 555c is provided over the insulating layer 555b.

An inorganic insulating film can be suitably used for each of the insulating layers 555a, 555b, and 555c. For example, it is preferable that a silicon oxide film be used for each of the insulating layers 555a and 555c and that a silicon nitride film be used for the insulating layer 555b. This enables the insulating layer 555b to function as an etching protective film. Although this embodiment describes an example in which the insulating layer 555c is partly etched and a depressed portion is formed, the depressed portion is not necessarily provided in the insulating layer 555c.

The light-emitting elements 110R, 110G, and 110B are provided over the insulating layer 555c.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are shared by the light-emitting elements 110R, 110G, and 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layers 112R, 112G, and 112B can also be referred to as an EL layer and includes at least a layer containing a light-emitting organic compound (a light-emitting layer).

In the display device 500A, since the light-emitting devices of different colors are separately formed, a change in chromaticity between light emission at low luminance and light emission at high luminance is small. Furthermore, since the organic layers 112R, 112G, and 112B are separated from each other, crosstalk generated between adjacent subpixels can be inhibited while the display panel has high resolution. It is thus possible to achieve a display panel that has high resolution and high display quality.

In a region between adjacent light-emitting elements, an insulating layer 125, a resin layer 126, and a layer 128 are provided.

The pixel electrodes 111R, 111G, and 111B of the light-emitting elements are each electrically connected to the conductive layer 355 of the transistor 320 through a plug 556 that is embedded in the insulating layers 555a, 555b, and 555c, the conductive layer 541 that is embedded in the insulating layer 554, and the plug 574. The top surface of the insulating layer 555c and the top surface of the plug 556 are level with or substantially level with each other. A variety of conductive materials can be used for the plugs.

A protective layer 121 is provided over the light-emitting elements 110R, 110G, and 110B. A substrate 170 is attached onto the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely narrowed. Accordingly, the display device can have high resolution or high definition.

At least part of this embodiment can be implemented as appropriate in combination with any of the other embodiments described in this specification.

### Embodiment 6

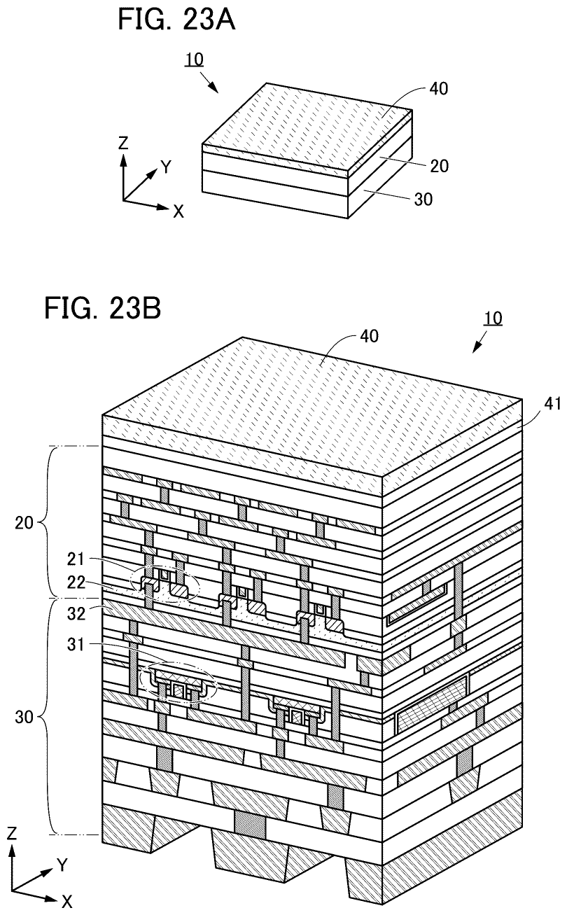

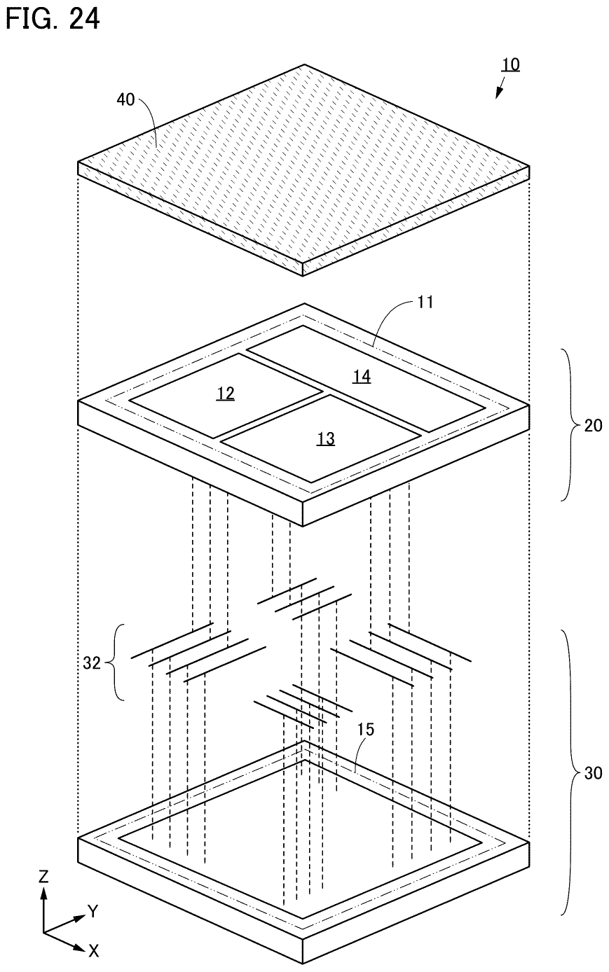

A semiconductor device of one embodiment of the present invention will be described. FIG. 23A is a schematic perspective view of a semiconductor device 10 of one embodiment of the present invention. FIG. 23B is a schematic perspective view of part of the semiconductor device 10. FIG. 24 is a schematic perspective view illustrating a structure of the semiconductor device 10.

In FIGS. 23A and 23B and FIG. 24, the semiconductor device 10 includes an element layer 30 under an element layer 20 including a substrate 22 that is a semiconductor substrate, and a support substrate 40 over the element layer 20 with an insulating layer 41 therebetween. The element layer 20 includes a plurality of transistors 21 included in a functional circuit 11. The element layer 30 includes a plurality of transistors 31 included in a switch circuit 15. The transistor 31 functions as a switch for controlling conduction and non-conduction between a line for supplying power from the outside and a conductive layer 32 functioning as a power supply line.

As the transistor 31, the transistor shown in Embodiment 2 can be used.

The transistor 21 included in the element layer 20 is formed on a surface (also referred to as a “first surface”) side of the substrate 22. The element layer 30 is formed on the rear surface (also referred to as a surface opposite to the surface or a “second surface”) side of the substrate 22. Thus, the transistor 31 included in the element layer 30 is formed on the second surface side of the substrate 22.

In FIG. 24, a CPU 12, a GPU 13, and a memory 14 are shown as examples of the functional circuit 11.

Note that the functional circuit 11 is not limited to the CPU 12, the GPU 13, and the memory 14, and one or more of these can be used. In addition, the functional circuit can include a circuit having other functions.

In order to realize an increase in operation speed, an increase in mounting density, and power saving of the semiconductor device 10, scaling down and thinning of a transistor, a wiring, and the like and a reduction in power supply potential are required for the functional circuit 11. The switch circuit 15 is capable of controlling whether to supply or stop voltage supplied from the outside to each circuit included in the functional circuit 11. Thus, supply of a power supply potential to a circuit in a standby state can be stopped, so that power consumption can be reduced.

The transistor included in the switch circuit 15 is required to have high withstand voltage. One of effective ways of increasing the withstand voltage of the transistor is to increase the thickness of a gate insulating film. In this manner, the transistors 21 and 31 are required to have different performances. Thus, different measures for improving the characteristics are required for the transistors 21 and 31.

The functional circuit 11 is required to be scaled down and thinned. Thus, when the switch circuit 15 and the functional circuit 11 are formed with the same process node, not only a lead wiring but also a wiring for supplying power (power supply line) becomes thin, so that sufficient power cannot be supplied to the functional circuit 11. In addition, scaling down increases the wiring resistance to easily cause unevenness of the power supply potential in the functional circuit 11 due to a voltage drop. To stably supply power to the functional circuit 11, the wiring included in the switch circuit 15 preferably has a lower wiring resistance than the wiring included in the functional circuit 11. In particular, the wiring functioning as a power supply line preferably has a lower wiring resistance than the wiring included in the functional circuit 11. One of effective ways of reducing the wiring resistance is to increase the cross-sectional area of a conductive layer functioning as a wiring. Note that in order to increase the cross-sectional area of the conductive layer, it is necessary to increase one or both of the width and the height of the conductive layer. In view of the above, different process nodes are suitably used for the functional circuit 11 and the switch circuit 15.

In the semiconductor device 10 of one embodiment of the present invention, the functional circuit 11 and the switch circuit 15 are provided in different element layers, whereby different improvement measures can be taken for the functional circuit 11 and the switch circuit 15. The functional circuit 11 and the switch circuit 15 can be formed with different process nodes.

In one embodiment of the present invention, a plurality of conductive layers 32 functioning as power supply lines and the switch circuit 15 can be placed under the functional circuit 11, so that the area occupied by the semiconductor device 10 can be reduced. The element layer 30 provided to overlap with the element layer 20 is preferably formed by a thin film formation technique such as a CVD method or a sputtering method. Thus, the transistor 31 included in the element layer 30 is preferably a thin film transistor.

At least some of the plurality of conductive layers 32 included in the element layer 30 can function as a power supply line. In the case where the element layer 30 includes a clock signal generation circuit, at least some of the plurality of conductive layers 32 can function as a clock signal line. One or both of power supply supplied from the outside and a clock signal can be supplied to the functional circuit 11 included in the element layer 20 through at least some of the plurality of conductive layers 32.

For example, it is possible to manufacture a die (a semiconductor chip) including the functional circuit 11 and a die including the switch circuit 15 separately to be mechanically bonded to each other by a three-dimensional integration technique. However, a reduction in the pitch of a connection portion is difficult to achieve in the three-dimensional integration technique because the dies are mechanically bonded to each other, which makes it difficult to improve the alignment accuracy, and the size of a bump used for connecting the dies is difficult to reduce, for example. As a result, there is a problem in that the wiring lead distance for supplying power to an intended portion of the functional circuit 11 is difficult to be shortened.

In one embodiment of the present invention, the element layer 30 including the switch circuit 15 is formed on the rear surface side of the substrate 22 by a thin film formation technique and a photolithography technique, for example. Thus, the semiconductor device 10 of one embodiment of the present invention is a semiconductor device having a monolithic stacked-layer structure.

When the element layer 30 is formed with use of a thin film formation technique, alignment with high accuracy at a photolithography level can be achieved. Furthermore, the conductive layer functioning as a power supply line can be connected to an intended portion of the functional circuit 11 with an extremely short distance. Thus, power with a required voltage can be supplied to an intended portion of the functional circuit 11. In the semiconductor device 10 of one embodiment of the present invention, the connection distance between the switch circuit 15 and the functional circuit 11 is short; thus, power loss due to power transmission is reduced, so that power consumption can be reduced.

At least part of this embodiment can be implemented as appropriate in combination with any of the other embodiments described in this specification.

### Embodiment 7

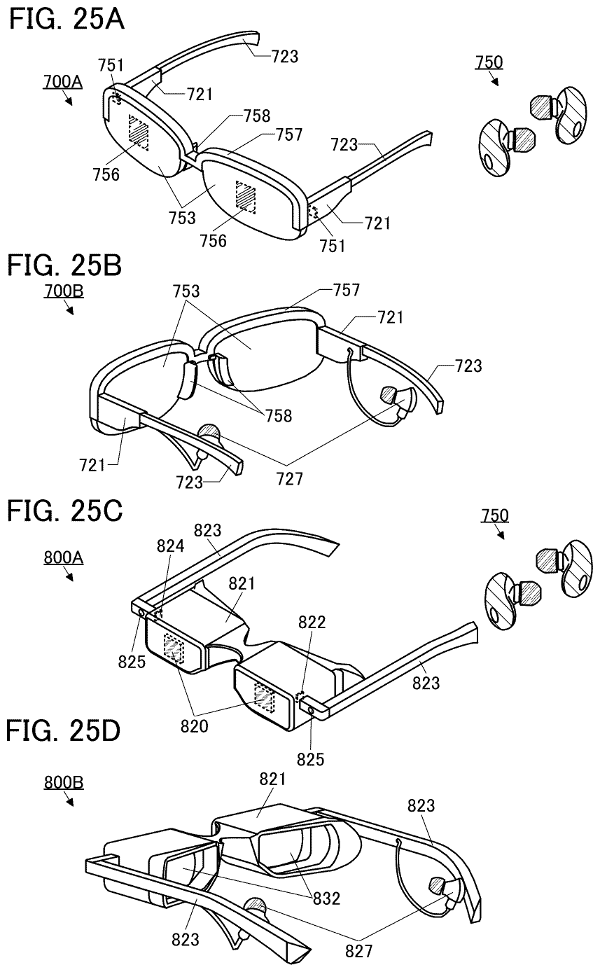

In this embodiment, electronic apparatuses of one embodiment of the present invention will be described with reference to FIGS. 25A to 25D, FIGS. 26A to 26F, and FIGS. 27A to 27G.

Electronic apparatuses in this embodiment each include a display panel (display device) employing the transistor of one embodiment of the present invention in a display portion. The display device of one embodiment of the present invention can easily achieve higher resolution and definition and can achieve high display quality. Thus, the display device of one embodiment of the present invention can be used for display portions of a variety of electronic apparatuses.

Examples of the electronic apparatuses include a digital camera, a digital video camera, a digital photo frame, a cellular phone, a portable game machine, a portable information terminal, and an audio reproducing device, in addition to electronic apparatuses with comparatively large screens, such as a television device, a desktop or laptop personal computer, a monitor for a computer or the like, digital signage, and a large game machine such as a pachinko machine.

In particular, the display panel of one embodiment of the present invention can have higher resolution, and thus can be suitably used for an electronic apparatus having a comparatively small display portion. Examples of such an electronic apparatus include wristwatch-type and bracelet-type information terminal devices (wearable devices) and a wearable device that can be worn on a head, such as a device for VR such as a head-mounted display, a glasses-type device for AR, or a device for MR.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel with one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic apparatus in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic apparatus in this embodiment can have a variety of functions. For example, the electronic apparatus can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described with reference to FIG. 25A to FIG. 25D. These wearable devices have one or both of a function of displaying AR contents and a function of displaying VR contents. Note that the wearable devices may have a function of displaying SR or MR contents, in addition to AR and VR contents. The electronic apparatus having a function of displaying contents of at least one of AR, VR, SR, MR, and the like enables the user to reach a higher level of immersion.

An electronic apparatus 700A illustrated in FIG. 25A and an electronic apparatus 700B illustrated in FIG. 25B each include a pair of display panels 751, a pair of housings 721, a communication portion (not illustrated), a pair of wearing portions 723, a control portion (not illustrated), an imaging portion (not illustrated), a pair of optical members 753, a frame 757, and a pair of nose pads 758.

The display panel of one embodiment of the present invention can be employed for the display panel 751. Thus, the electronic apparatus can perform display with extremely high resolution.

The electronic apparatus 700A and the electronic apparatus 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic apparatus 700A and the electronic apparatus 700B are electronic apparatuses capable of AR display.

In each of the electronic apparatus 700A and the electronic apparatus 700B, a camera capable of capturing images of the front side may be provided as the imaging portion. Furthermore, when each of the electronic apparatus 700A and the electronic apparatus 700B is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power supply potential can be connected may be provided.

Each of the electronic apparatuses 700A and 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic apparatus 800A illustrated in FIG. 25C and an electronic apparatus 800B illustrated in FIG. 25D each include a pair of display portions 820, a housing 821, a communication portion 822, a pair of wearing portions 823, a control portion 824, a pair of imaging portions 825, and a pair of lenses 832.

The display panel of one embodiment of the present invention can be employed in the display portion 820. Thus, the electronic apparatus can perform display with extremely high resolution. This enables the user to feel a high sense of immersion.

The display portions 820 are positioned inside the housing 821 to be seen through the lenses 832. Furthermore, when the pair of display portions 820 display different images, 3D display using parallax can be also performed.

The electronic apparatuses 800A and 800B can be regarded as electronic apparatuses for VR. The user who wears the electronic apparatus 800A or 800B can see images displayed on the display portions 820 through the lenses 832.

The electronic apparatuses 800A and 800B each preferably include a mechanism for adjusting the lateral positions of the lenses 832 and the display portions 820 so that the lenses 832 and the display portions 820 are positioned optimally in accordance with the positions of the user's eyes. In addition, the electronic apparatuses 800A and 800B preferably include a mechanism for adjusting focus by changing the distance between the lenses 832 and the display portions 820.

The electronic apparatus 800A or 800B can be worn on the user's head with the wearing portions 823. Note that FIG. 25C and the like illustrate examples where the wearing portion 823 has a shape like a temple of glasses; however, one embodiment of the present invention is not limited thereto. The wearing portion 823 can have any shape with which the user can wear and can have a shape of a helmet or a band, for example.

The imaging portion 825 has a function of obtaining external information. Data obtained by the imaging portion 825 can be output to the display portion 820. An image sensor can be used for the imaging portion 825. Moreover, a plurality of cameras may be provided to support a plurality of fields of view, such as a telescope field of view and a wide field of view.

Although an example of including the imaging portion 825 is shown here, a range sensor (hereinafter also referred to as a sensing portion) capable of measuring the distance between the user and an object just needs to be provided. That is, the imaging portion 825 is one embodiment of the sensing portion. For the sensing portion, an image sensor or a distance image sensor such as a light detection and ranging (LiDAR) sensor can be used, for example. By using images obtained by the camera and images obtained by the distance image sensor, more information can be obtained and a gesture operation with higher accuracy is possible.

The electronic apparatus 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic apparatus 800A.

The electronic apparatuses 800A and 800B may each include an input terminal. To the input terminal, a cable for supplying a video signal from a video output device or the like, power for charging a battery provided in the electronic apparatus, and the like can be connected.

An electronic apparatus of one embodiment of the present invention may have a function of performing wireless communication with earphones 750. The earphones 750 include a communication portion (not illustrated) and have a wireless communication function. The earphones 750 can receive information (e.g., audio data) from the electronic apparatus with the wireless communication function. For example, the electronic apparatus 700A illustrated in FIG. 25A has a function of transmitting information to the earphones 750 with the wireless communication function. As another example, the electronic apparatus 800A illustrated in FIG. 25C has a function of transmitting information to the earphones 750 with the wireless communication function.

The electronic apparatus may include an earphone portion. The electronic apparatus 700B illustrated in FIG. 25B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic apparatus 800B illustrated in FIG. 25D includes earphone portions 827. For example, the earphone portions 827 and the control portion 824 can be connected to each other by wire. Part of a wiring that connects the earphone portions 827 and the control portion 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

Note that the electronic apparatus may include an audio output terminal to which earphones, headphones, or the like can be connected. The electronic apparatus may include one or both of an audio input terminal and an audio input mechanism. As the audio input mechanism, a sound collecting device such as a microphone can be used, for example. The electronic apparatus may have a function of what is called a headset by including the audio input mechanism.

As described above, both the glasses-type device (e.g., the electronic apparatuses 700A and 700B) and the goggles-type device (e.g., the electronic apparatuses 800A and 800B) are suitable for the electronic apparatus of one embodiment of the present invention.

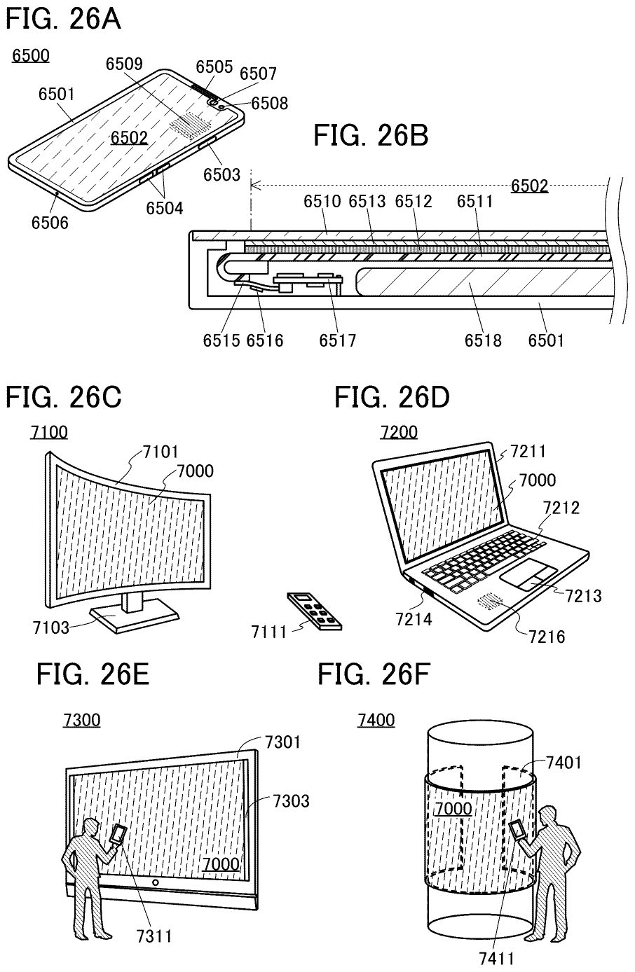

An electronic apparatus 6500 illustrated in FIG. 26A is a portable information terminal device that can be used as a smartphone.

The electronic apparatus 6500 includes a housing 6501, a display portion 6502, a power button 6503, buttons 6504, a speaker 6505, a microphone 6506, a camera 6507, a light source 6508, a control device 6509, and the like. The display portion 6502 has a touch panel function. Note that one or more selected from a CPU, a GPU, and a memory device are included as the control device 6509, for example. The semiconductor device of one embodiment of the present invention can be employed for the display portion 6502, the control device 6509, and the like. The semiconductor device of one embodiment of the present invention is suitably used for the control device 6509 because power consumption can be reduced.

The display panel of one embodiment of the present invention can be employed for the display portion 6502.

FIG. 26B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be employed for the display panel 6511. Thus, an extremely lightweight electronic apparatus can be achieved. In addition, since the display panel 6511 is extremely thin, the battery 6518 with high capacity can be mounted while the thickness of the electronic apparatus is reduced. Moreover, part of the display panel 6511 is folded back so that a connection portion with the FPC 6515 is provided on the back side of a pixel portion, so that an electronic apparatus with a narrow bezel can be achieved.

FIG. 26C illustrates an example of a television device. In a television device 7100, a display portion 7000 is incorporated in a housing 7101. Here, a structure in which the housing 7101 is supported by a stand 7103 is illustrated.

Operation of the television device 7100 illustrated in FIG. 26C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and a video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 26D illustrates an example of a laptop personal computer. A laptop personal computer 7200 includes a housing 7211, a keyboard 7212, a pointing device 7213, an external connection port 7214, a control device 7216, and the like. The display portion 7000 is incorporated in the housing 7211. One or more selected from a CPU, a GPU, and a memory device are included as the control device 7216, for example. The semiconductor device of one embodiment of the present invention can be employed for the display portion 7000, the control device 7216, and the like. The semiconductor device of one embodiment of the present invention is suitably used for the control device 7216 because power consumption can be reduced.

FIGS. 26E and 26F illustrate examples of digital signage.

Digital signage 7300 illustrated in FIG. 26E includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 26F is digital signage 7400 attached to a cylindrical pillar 7401. The digital signage 7400 includes the display portion 7000 provided along a curved surface of the pillar 7401.

A larger display portion 7000 can increase the amount of information that can be provided at a time. The larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, for an application for providing information such as route information or traffic information, usability can be increased by an intuitive operation.

As illustrated in FIGS. 26E and 26F, it is preferable that the digital signage 7300 or 7400 can work with an information terminal device 7311 or an information terminal device 7411 such as a user's smartphone through wireless communication. For example, information of an advertisement displayed on the display portion 7000 can be displayed on a screen of the information terminal device 7311 or 7411. Furthermore, by the operation of the information terminal device 7311 or 7411, display on the display portion 7000 can be switched.

It is also possible to make the digital signage 7300 or 7400 execute a game with the use of the screen of the information terminal device 7311 or 7411 as an operation means (a controller). Thus, an unspecified number of users can join in and enjoy the game concurrently.

The display panel of one embodiment of the present invention can be employed for the display portion 7000 illustrated in each of FIGS. 26C to 26F.

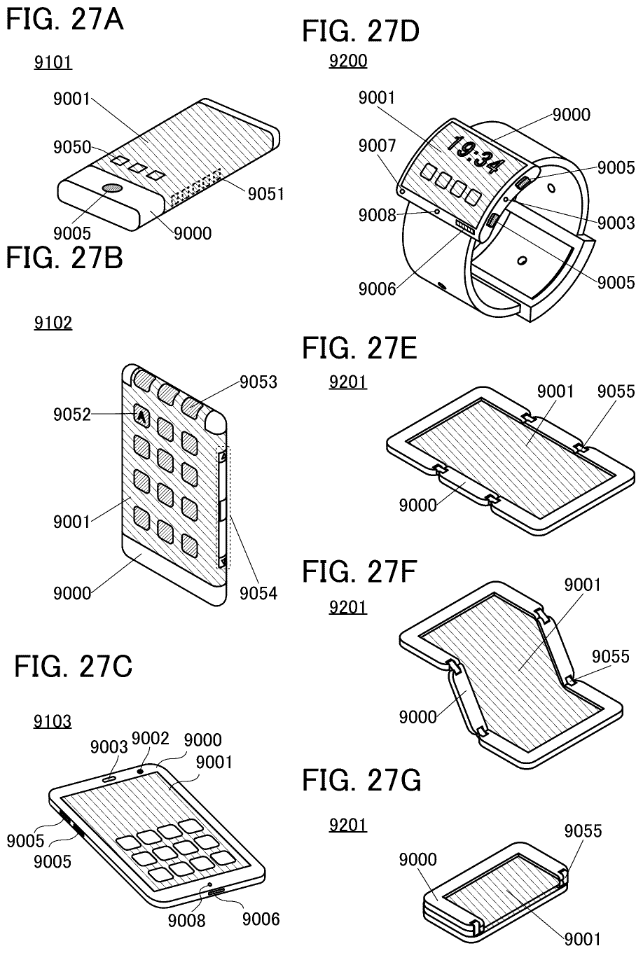

Electronic apparatuses illustrated in FIG. 27A to FIG. 27G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic apparatuses illustrated in FIGS. 27A to 27G have a variety of functions. For example, the electronic apparatuses can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic apparatuses are not limited thereto, and the electronic apparatuses can have a variety of functions. The electronic apparatuses may include a plurality of display portions. In addition, the electronic apparatus may each be provided with a camera or the like and have a function of taking a still image or a moving image and storing the taken image in a recording medium (an external recording medium or a recording medium incorporated in the camera), a function of displaying the taken image on the display portion, or the like.

The electronic apparatuses illustrated in FIGS. 27A to 27G are described in detail below.

FIG. 27A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 27A illustrates an example in which three icons 9050 are displayed. Furthermore, information 9051 indicated by dashed rectangles can be displayed on another surface of the display portion 9001. Examples of the information 9051 include notification of incoming e-mails, SNS messages, calls, and the like, the titles and senders of e-mails, SNS messages, and the like, the date, the time, remaining battery, and radio field intensity. Alternatively, the icon 9050 or the like may be displayed at the position where the information 9051 is displayed.

FIG. 27B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed such that it can be seen from above the portable information terminal 9102, with the portable information terminal 9102 put in a breast pocket of his/her clothes. The user can see display without taking out the portable information terminal 9102 from the pocket and decide whether to answer a call, for example.

FIG. 27C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface of the housing 9000.

FIG. 27D is a perspective view illustrating a wristwatch-type portable information terminal 9200. For example, the portable information terminal 9200 can be used as a Smartwatch (registered trademark). A display surface of the display portion 9001 is provided to be curved, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIGS. 27E to 27G are perspective views illustrating a foldable portable information terminal 9201. FIG. 27E is a perspective view of the portable information terminal 9201 that is opened, FIG. 27G is a perspective view of the portable information terminal 9201 that is folded, and FIG. 27F is a perspective view of the portable information terminal 9201 that is shifted from one of the states in FIGS. 27E and 27G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented as appropriate in combination with any of the other embodiments described in this specification.

### Embodiment 8

In this embodiment, application examples of the semiconductor device of one embodiment of the present invention will be described. The semiconductor device of one embodiment of the present invention can be used for an electronic component, an electronic apparatus, a large computer, space equipment, and a data center (also referred to as DC), for example. An electronic component, an electronic apparatus, a large computer, space equipment, and a data center each using the semiconductor device of one embodiment of the present invention are effective in achieving high performance, e.g., reducing power consumption.

An electronic component or the like employing the semiconductor device of one embodiment of the present invention can be employed for the electronic apparatus shown in Embodiment 7.

### [Electronic Component]

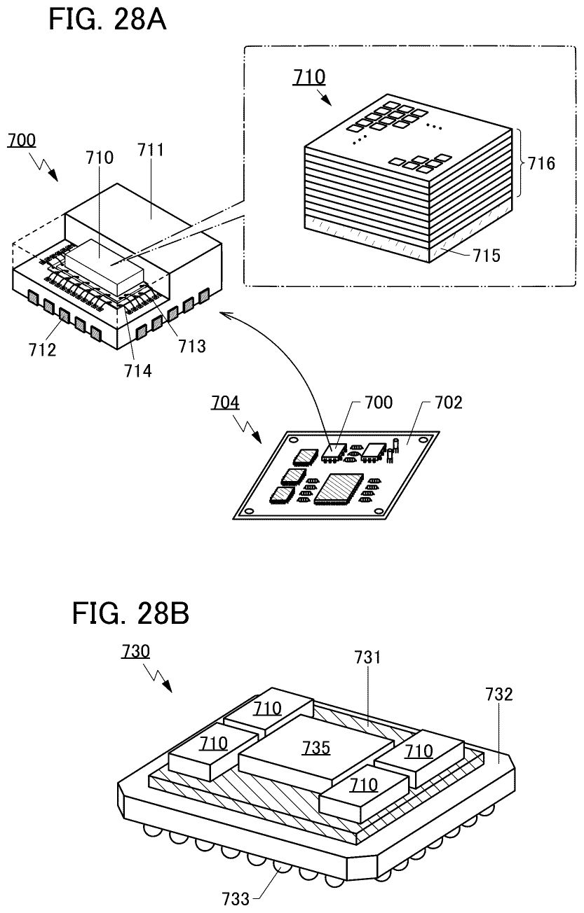

FIG. 28A illustrates a perspective view of a substrate (a mounting board 704) on which an electronic component 700 is mounted. The electronic component 700 illustrated in FIG. 28A includes a semiconductor device 710 in a mold 711. FIG. 28A omits illustrations of some parts to show the inside of the electronic component 700. The electronic component 700 includes lands 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to a period of time from data access to the start of data transmission. In the case where Si transistors are used for the memory layer 716, the monolithic stacked-layer structure is difficult to form as compared with the case where OS transistors are used for the memory layer 716. Therefore, OS transistors are superior to Si transistors in the monolithic stacked-layer structure.

The semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 28B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate”. In some cases, a through electrode is provided in the interposer 731 to be used for electrically connecting an integrated circuit and the package substrate 732. In a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in the expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (a radiator plate) may be provided to overlap with the electronic component 730. In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom part of the package substrate 732 to mount the electronic component 730 on another substrate. FIG. 28B illustrates an example in which the electrodes 733 are formed of solder balls. When the solder balls are provided in a matrix on the bottom part of the package substrate 732, ball grid array (BGA) mounting can be achieved. Alternatively, the electrodes 733 may be formed of conductive pins. When the conductive pins are provided in a matrix on the bottom part of the package substrate 732, pin grid array (PGA) mounting can be achieved.

The electronic component 730 can be mounted on another substrate by a variety of mounting methods other than BGA and PGA. Examples of mounting methods include staggered pin grid array (SPGA), land grid array (LGA), quad flat package (QFP), quad flat J-leaded package (QFJ), and quad flat non-leaded package (QFN).

### [Large Computer]

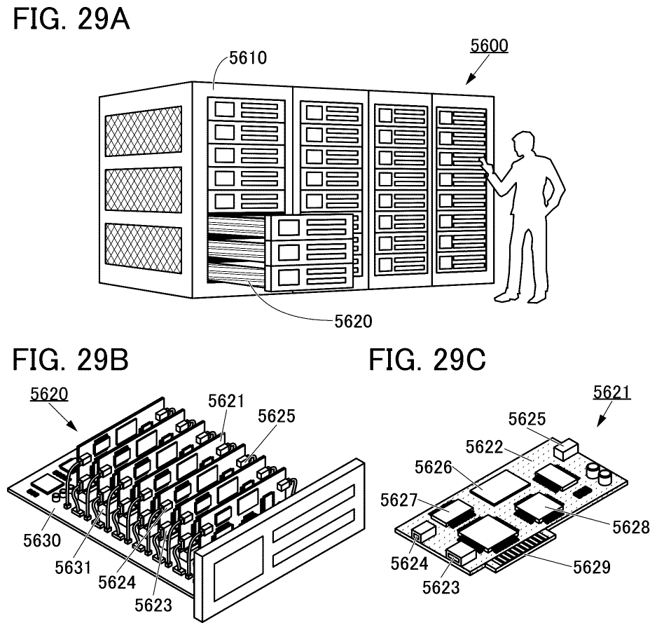

FIG. 29A illustrates a perspective view of a large computer 5600. In the large computer 5600, a plurality of rack mount computers 5620 are stored in a rack 5610. Note that the large computer 5600 may also be referred to as a supercomputer.

FIG. 29B illustrates a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 29C illustrates an example of the PC card 5621. The PC card 5621 is a processing board provided with a CPU, a GPU, a memory device, and the like, for example. The PC card 5621 includes a board 5622, and components mounted on the board 5622, such as the connection terminal 5623, the connection terminal 5624, the connection terminal 5625, an electronic component 5626, an electronic component 5627, an electronic component 5628, and a connection terminal 5629. Note that FIG. 29C illustrates components other than the electronic components 5626, 5627, and 5628.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can each serve as, for example, an interface for performing power supply, signal input, or the like to the PC card 5621. As another example, the connection terminals 5623, 5624, and 5625 can each serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The electronic component 5626 includes a terminal (not illustrated) for inputting and outputting signals, and when the terminal is inserted in a socket (not illustrated) of the board 5622, the electronic component 5626 and the board 5622 can be electrically connected to each other.

The electronic components 5627 and 5628 each include a plurality of terminals, and when the terminals are reflow-soldered, for example, to wirings of the board 5622, the electronic components 5627 and 5628 can be mounted. Examples of the electronic component 5627 include an FPGA, a GPU, and a CPU. The electronic component 730 can be used as the electronic component 5627, for example. An example of the electronic component 5628 is a memory device. The electronic component 700 can be used as the electronic component 5628, for example.

The large computer 5600 can also function as a parallel computer. When the large computer 5600 is used as a parallel computer, large-scale computation necessary for artificial intelligence learning and inference can be performed, for example.

At least part of this embodiment can be implemented as appropriate in combination with any of the other embodiments described in this specification.

This application is based on Japanese Patent Application Serial No. 2024-207489 filed with Japan Patent Office on Nov. 28, 2024, the entire contents of which are hereby incorporated by reference.

What is claimed is:

1. A semiconductor device comprising:
a substrate;
a semiconductor layer;
a gate insulating layer; and
a gate electrode,
wherein the semiconductor layer is in contact with a top surface of the substrate,
wherein the semiconductor layer comprises a first region, a second region, and a third region,
wherein the first region overlaps with the gate electrode with the gate insulating layer therebetween,
wherein the first region is interposed between the second region and the third region,
wherein the substrate has a single crystal structure,
wherein the semiconductor layer comprises indium oxide having a single crystal structure,
wherein the second region and the third region comprise a first element, and
wherein the first element is at least one of titanium, tantalum, tungsten, molybdenum, tin, silicon, germanium, zirconium, hafnium, antimony, magnesium, hydrogen, boron, and phosphorus.

2. A semiconductor device comprising:
a substrate;
a semiconductor layer;
a gate insulating layer; and
a gate electrode,
wherein the semiconductor layer is in contact with a top surface of the substrate,
wherein the semiconductor layer comprises a first region, a second region and a third region,
wherein the first region overlaps with the gate electrode with the gate insulating layer therebetween,
wherein the first region is interposed between the second region and the third region,
wherein the substrate comprises aluminum oxide having a single crystal structure,
wherein the top surface of the substrate is a (0001) plane or a plane equivalent to the (0001) plane,
wherein the semiconductor layer comprises indium oxide having a single crystal structure,
wherein a surface of the semiconductor layer in contact with the substrate is a (111) plane or a plane equivalent to the (111) plane,
wherein the second region and the third region comprise a first element, and
wherein the first element is at least one of titanium, tantalum, tungsten, molybdenum, tin, silicon, germanium, zirconium, hafnium, antimony, magnesium, hydrogen, boron, and phosphorus.

3. The semiconductor device according to claim 2,
wherein an off-angle of the substrate is 0°.

4. The semiconductor device according to claim 2,
wherein an off-angle of the substrate is greater than 0° and less than or equal to 10°.

5. The semiconductor device according to claim 3,
wherein a direction of the off-angle is parallel to a [−2110] orientation of the substrate or an orientation equivalent to the [−2110] orientation.

6. A method for manufacturing a semiconductor device, comprising:
forming a single crystal semiconductor film over a single crystal substrate;
processing the single crystal semiconductor film to form an island-shaped semiconductor layer;
forming a mask layer covering a first region of the island-shaped semiconductor layer;
adding a first element to a second region and a third region of the island-shaped semiconductor layer between which the first region is interposed;
forming a first insulating layer covering the island-shaped semiconductor layer and the mask layer;
planarizing the first insulating layer until a top surface of the mask layer is exposed;
removing the mask layer to form a groove portion reaching the island-shaped semiconductor layer in the first insulating layer; and
sequentially forming a gate insulating layer and a gate electrode in the groove portion,
wherein aluminum oxide having a single crystal structure is used for the single crystal substrate,
wherein indium oxide is used for the island-shaped semiconductor layer, and
wherein at least one of titanium, tantalum, tungsten, molybdenum, tin, silicon, germanium, zirconium, hafnium, antimony, magnesium, hydrogen, boron, and phosphorus is used as the first element.

7. The method for manufacturing a semiconductor device, according to claim 6,
wherein the single crystal substrate comprises a formation surface, the formation surface being a (0001) plane or a plane equivalent to the (0001) plane, and
wherein the single crystal semiconductor film comprises a surface in contact with the single crystal substrate, the surface being a (111) plane or a plane equivalent to the (111) plane.

8. The method for manufacturing a semiconductor device, according to claim 6,
wherein a substrate having an off-angle is used as the single crystal substrate, and
wherein the off-angle is greater than 0° and less than or equal to 10°.

9. The method for manufacturing a semiconductor device, according to claim 8,
wherein a direction of the off-angle is parallel to a [−2110] orientation of the single crystal substrate or an orientation equivalent to the [−2110] orientation.
